(19) United States
(12) Patent Application Publication
(10) Pub. No.: US 2016/0099247 A1
(43) Pub. Date: Apr. 7, 2016

(54) SEMICONDUCTOR DEVICES WITH CAPACITORS

(71) Applicants: Taejin Park, Yongin-si (KR); Jemin Park, Suwon-si (KR); Daeik Kim, Hwaseong-si (KR); Woojin Kim, Guri-si (KR); Kiseok Lee, Busan (KR); Yoosang Hwang, Suwon-si (KR)

(72) Inventors: Taejin Park, Yongin-si (KR); Jemin Park, Suwon-si (KR); Daeik Kim, Hwaseong-si (KR); Woojin Kim, Guri-si (KR); Kiseok Lee, Busan (KR); Yoosang Hwang, Suwon-si (KR)

(21) Appl. No.: 14/874,897

(22) Filed: Oct. 5, 2015

(30) Foreign Application Priority Data
Oct. 7, 2014 (KR) 10-2014-0135060

(51) Int. Cl. H01L 27/108; H01L 49/02

(52) U.S. Cl. CPC H01L 27/10814; H01L 28/86

(57) ABSTRACT

A semiconductor device includes bottom electrodes two-dimensionally arranged on a substrate and transistors connected to the bottom electrodes, respectively. Each of the bottom electrodes may include first side surfaces facing each other in a first direction and second side surfaces facing each other in a second direction crossing the first direction. At least one of the first and second side surfaces may have a concave shape, when viewed in a plan view.

### CROSS-REFERENCE TO RELATED APPLICATIONS

This U.S. non-provisional patent application claims priority under 35 U.S.C. §119 to Korean Patent Application No. 10-2014-0135060, filed on Oct. 7, 2014, in the Korean Intellectual Property Office, the entire contents of which are hereby incorporated by reference.

### BACKGROUND OF THE INVENTION

Example embodiments of the inventive concept relate to a semiconductor device, and in particular, to a semiconductor device with a capacitor.

As semiconductor devices become more highly integrated, it may be necessary to realize a capacitor having sufficiently high capacitance in a limited area. The capacitance of a capacitor is proportional to a surface area of an electrode and a dielectric constant of dielectric film and is inversely proportional to an equivalent oxide thickness of the dielectric film. This means that the capacitance of a capacitor can be increased, for example, by forming a three dimensional electrode to increase a surface area thereof, decreasing an equivalent oxide thickness of the dielectric film, or using a dielectric film having a high dielectric constant.

The surface area of electrode can be increased by increasing a height of a bottom electrode (or a storage electrode), increasing an effective surface area of the bottom electrode (for example, using a hemi-spherical grain (HSG)), or forming a cylindrical bottom electrode, whose both inner and outer side surfaces can be used as the surface area of the capacitor. Metal oxides (e.g., TiO₂ or Ta₂O₅) or perovskite ferroelectric materials (e.g., PZT (PbZrTiO₃) or BST (BaSrTiO₃)) may be used as the dielectric film having a generally high dielectric constant.

### SUMMARY

Example embodiments of the inventive concept provide a semiconductor device, in which a capacitor with higher capacitance is provided.

According to example embodiments of the inventive concept, a semiconductor device may include bottom electrodes two-dimensionally arranged on a substrate, and transistors connected to the bottom electrodes, respectively. Each of the bottom electrodes may include first side surfaces facing each other in a first direction and second side surfaces facing each other in a second direction crossing the first direction. A first one of the first side surfaces of a first one of the bottom electrodes is spaced apart from one of the side surfaces of a second one of the bottom electrodes adjacent thereto in the first direction by a first distance. A first one of the second side surfaces of the first one of the bottom electrodes is spaced apart from one of the side surfaces of a third one of the bottom electrodes adjacent thereto in the second direction by a second distance. At least one of the first and second side surfaces may have a concave shape, when viewed in a plan view.

In example embodiments, a second one of the first side surfaces of the first one of the bottom electrodes is spaced apart from one of the side surfaces of a fourth one of the bottom electrodes adjacent thereto in the first direction by the first distance, a second one of the second side surfaces of the first one of the bottom electrodes is spaced apart from one of the side surfaces of a fifth one of the bottom electrodes adjacent thereto in the second direction by the second distance, the first and second distances may be a minimum separation distance required for electrical separation between the bottom electrodes adjacent to each other.

In example embodiments, the first and second distances may be substantially equal to each other.

In example embodiments, the device may further include bit lines provided between the bottom electrodes and the transistors and connected to the transistors.

In example embodiments, when viewed in a plan view, the first side surfaces may have shapes substantially symmetrical to each other.

In example embodiments, each of the first side surfaces may have a concave shape.

In example embodiments, when viewed in a plan view, the second side surfaces may have shapes substantially symmetrical to each other, and each of the second side surfaces may have a concave shape.

In example embodiments, when viewed in a plan view, the second side surfaces may have shapes substantially symmetrical to each other, and each of the second side surfaces may have a linear shape extending parallel to the first direction.

In example embodiments, when viewed in a plan view, the second side surfaces may have shapes substantially symmetrical to each other, and each of the second side surfaces may have a convex shape.

In example embodiments, each of the first side surfaces may have a linear shape extending parallel to the second direction.

In example embodiments, when viewed in a plan view, the first side surfaces may have shapes substantially symmetrical to each other, and each of the first side surfaces may have a convex shape.

In example embodiments, when viewed in a plan view, the first side surfaces may have shapes substantially asymmetrical to each other.

In example embodiments, one of the first side surfaces may have a concave shape, and the other of the first side surfaces may have a convex shape.

In example embodiments, when viewed in a plan view, the second side surfaces may have shapes substantially symmetrical to each other, and each of the second side surfaces may have a concave shape.

In example embodiments, when viewed in a plan view, the second side surfaces may have shapes substantially symmetrical to each other, and each of the second side surfaces may have a linear shape extending parallel to the first direction.

In example embodiments, when viewed in a plan view, the second side surfaces may have shapes substantially symmetrical to each other, and each of the second side surfaces may have a convex shape.

In example embodiments, when viewed in a plan view, the second side surfaces may have shapes substantially asymmetrical to each other. One of the second side surfaces may have a concave shape, and the other of the second side surfaces may have a convex shape.

In example embodiments, each of the bottom electrodes may further include third side surfaces facing each other in a third direction crossing both the first and second directions. A first one of the third side surfaces of the first one of the bottom electrodes is spaced apart from one of the side surfaces of a fourth one of the bottom electrodes adjacent thereto in the third direction by a third distance, and when viewed in a plan view, at least one of the first, second, and third side surfaces may have a concave shape.

In example embodiments, a second one of the first side surfaces of the first one of the bottom electrodes is spaced apart from one of the side surfaces of a fifth one of the bottom electrodes adjacent thereto in the first direction by the first distance, a second one of the second side surfaces of the first one of the bottom electrodes is spaced apart from one of the side surfaces of a sixth one of the bottom electrodes adjacent thereto in the second direction by the second distance, and a second one of the third side surfaces of the first one of the bottom electrodes is spaced apart from one of the side surfaces of a seventh one of the bottom electrodes adjacent thereto in the third direction by the third distance The first, second, and third distances may be a minimum separation distance required for electrical separation between the bottom electrodes adjacent to each other.

In example embodiments, the first, second, and third distances may be substantially the same.

In example embodiments, when viewed in a plan view, the first side surfaces may have shapes substantially symmetrical to each other, and each of the first side surfaces may have a concave shape.

In example embodiments, when viewed in a plan view, the first side surfaces may have shapes substantially asymmetrical to each other. One of the first side surfaces may have a concave shape, and the other of the first side surfaces may have a convex shape.

In example embodiments, when viewed in a plan view, the first side surfaces may have shapes substantially asymmetrical to each other. One of the first side surfaces may have a concave shape, and the other of the first side surfaces may have a linear shape extending parallel to the second direction.

In example embodiments, when viewed in a plan view, at least one of the first and second side surfaces may be concavely curved toward a center of the bottom electrode.

In example embodiments, when viewed in a plan view, one of the first and second side surfaces may have a concave shape and the other may have a convex shape. Here, the concave one of the first and second side surfaces of each of the bottom electrodes may be disposed to face a convex one of side surfaces of a neighboring one of the bottom electrodes.

In example embodiments, the device may further include a top electrode covering the bottom electrodes, and a dielectric layer interposed between the bottom electrodes and the top electrode.

According to example embodiments of the inventive concept, a semiconductor device may include bottom electrodes two-dimensionally arranged on a substrate, and transistors connected to the bottom electrodes, respectively. When viewed in a plan view, at least one of the bottom electrodes may have a shape different from the others.

In example embodiments, one of a pair of the bottom electrodes, whose shapes are different from each other in a plan view, may have a concavely-curved side surface, and the other of the pair of the bottom electrodes may have a convexly-curved side surface facing the concavely-curved side surface.

In example embodiments, each of the bottom electrodes may include first side surfaces facing each other in a first direction and second side surfaces facing each other in a second direction crossing the first direction. A first one of the first side surfaces of a first one of the bottom electrodes is spaced apart from one of the side surfaces of a second one of the bottom electrodes adjacent thereto in the first direction by a first distance. A first one of the second side surfaces of the first one of the bottom electrodes is spaced apart from one of the side surfaces of a third one of the bottom electrodes adjacent thereto in the second direction by a second distance.

In example embodiments, the first distance may be substantially equal to the second distance.

According to example embodiments of the inventive concept, a semiconductor device may include bottom electrodes two-dimensionally arranged on a substrate, and transistors connected to the bottom electrodes, respectively. When viewed in a plan view, each of the bottom electrodes may be shaped like a cross.

In example embodiments, each of the bottom electrodes may include first side surfaces extending parallel to a first direction and facing each other, second side surfaces extending parallel to a second direction crossing the first direction and facing each other, and third side surfaces connecting the first side surfaces to the second side surfaces. Here, each of the third side surfaces may include a first portion extending parallel to the first direction and a second portion extending parallel to the second direction. Further, each of the first side surfaces may be spaced apart from a side surface of a neighboring one of the bottom electrodes by a first distance, and each of the second side surfaces may be spaced apart from a side surface of another neighboring one of the bottom electrodes by a second distance. The first distance may be substantially equal to the second distance.

According to example embodiments of the inventive concept, a semiconductor device may include bottom electrodes two-dimensionally arranged on a substrate, and transistors connected to the bottom electrodes, respectively. When viewed in a plan view, each of the bottom electrodes may be shaped like a parallelogram.

In example embodiments, each of the bottom electrodes may include first side surfaces extending parallel to a first direction and facing each other and second side surfaces extending parallel to a third direction and facing each other, the third direction may be at an angle to both the first direction and a second direction orthogonal to the first direction, each of the first side surfaces may be spaced apart from a side surface of a neighboring one of the bottom electrodes by a first distance, each of the second side surfaces may be spaced apart from a side surface of another neighboring one of the bottom electrodes by a second distance, the first distance may be substantially equal to the second distance.

### BRIEF DESCRIPTION OF THE DRAWINGS

Example embodiments will be more clearly understood from the following brief description taken in conjunction with the accompanying drawings. The accompanying drawings represent non-limiting, example embodiments as described herein.

FIG. 1A is a plan view illustrating a semiconductor device according to an embodiment of the inventive concept.

FIG. 1B is a sectional view taken along line I-I′ of FIG. 1A.

FIG. 2 is a plan view illustrating a planar arrangement of bottom electrodes provided in the semiconductor device according to an embodiment of the inventive concept.

FIG. 3 is a plan view illustrating a planar shape of each bottom electrode provided in the semiconductor device according to an embodiment of the inventive concept.

FIGS. 4A through 4G are plan views illustrating modified planar shapes of each bottom electrode provided in the semiconductor device according to an embodiment of the inventive concept.

FIGS. 5A through 5K are plan views, each of which illustrates a modified planar arrangement of the bottom electrodes provided in the semiconductor device according to an embodiment of the inventive concept.

FIGS. 6A through 11A are plan views illustrating a method of fabricating a semiconductor device, according to an embodiment of the inventive concept.

FIGS. 6B through 11B are sectional views taken along lines I-I′ of FIGS. 6A through 11A, respectively.

FIG. 12A is a plan view illustrating a semiconductor device according to a further embodiment of the inventive concept.

FIG. 12B is a sectional view taken along line I-I′ of FIG. 12A.

FIG. 13 is a plan view illustrating a planar arrangement of bottom electrodes provided in the semiconductor device according to the further embodiment of the inventive concept.

FIG. 14 is a plan view illustrating a planar shape of each bottom electrode provided in the semiconductor device according to the further embodiment of the inventive concept.

FIGS. 15A through 15E are plan views illustrating modified planar shapes of each bottom electrode provided in the semiconductor device according to the further embodiment of the inventive concept.

FIGS. 16A through 16F are plan views, each of which illustrates a modified planar arrangement of the bottom electrodes provided in the semiconductor device according to the further embodiment of the inventive concept.

FIGS. 17A and 18A are plan views illustrating a method of fabricating a semiconductor device, according to a further embodiment of the inventive concept.

FIGS. 17B and 18B are sectional views taken along lines I-I′ of FIGS. 17A and 18A, respectively.

FIG. 19A is a plan view illustrating a semiconductor device according to still further embodiments of the inventive concept.

FIG. 19B is a sectional view taken along line I-I′ of FIG. 19A.

FIG. 20A is a plan view illustrating a semiconductor device according to still further embodiments of the inventive concept.

FIG. 20B is a sectional view taken along line I-I′ of FIG. 20A.

FIG. 21 is a plan view illustrating a modified planar shape of each bottom electrode provided in a semiconductor device according to example embodiments of the inventive concept.

FIGS. 22A and 22B are plan views illustrating planar arrangements of bottom electrodes, whose planar shapes are shaped like that shown in FIG. 21.

FIG. 23 is a plan view illustrating another modified planar shape of each bottom electrode provided in a semiconductor device according to example embodiments of the inventive concept.

FIGS. 24A and 24B are plan views illustrating planar arrangements of bottom electrodes, whose planar shapes are shaped like that shown in FIG. 23.

FIG. 25 is a schematic block diagram illustrating an example of electronic devices including a semiconductor device according to example embodiments of the inventive concept.

FIG. 26 is a schematic block diagram illustrating an example of memory cards including a semiconductor device according to example embodiments of the inventive concept.

It should be noted that these figures are intended to illustrate the general characteristics of methods, structure and/or materials utilized in certain example embodiments and to supplement the written description provided below. These drawings are not, however, to scale and may not precisely reflect the precise structural or performance characteristics of any given embodiment, and should not be interpreted as defining or limiting the range of values or properties encompassed by example embodiments. For example, the relative thicknesses and positioning of molecules, layers, regions and/or structural elements may be reduced or exaggerated for clarity. The use of similar or identical reference numbers in the various drawings is intended to indicate the presence of a similar or identical element or feature.

### DETAILED DESCRIPTION

Example embodiments of the inventive concepts will now be described more fully with reference to the accompanying drawings, in which example embodiments are shown. Example embodiments of the inventive concepts may, however, be embodied in many different forms and should not be construed as being limited to the embodiments set forth herein; rather, these embodiments are provided so that this disclosure will be thorough and complete, and will fully convey the concept of example embodiments to those of ordinary skill in the art. In the drawings, the thicknesses of layers and regions are exaggerated for clarity. Like reference numerals in the drawings denote like elements, and thus their description will be omitted.

It will be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present. Like numbers indicate like elements throughout the description. As used herein the term “and/or” includes any and all combinations of one or more of the associated listed items. Other words used to describe the relationship between elements or layers should be interpreted in a like fashion (e.g., “between” versus “directly between,” “adjacent” versus “directly adjacent,” “on” versus “directly on”).

It will be understood that, although the terms “first”, “second”, etc. may be used herein to describe various elements, components, regions, layers and/or sections, these elements, components, regions, layers and/or sections should not be limited by these terms. These terms are only used to distinguish one element, component, region, layer or section from another element, component, region, layer or section. Thus, a first element, component, region, layer or section discussed below could be termed a second element, component, region, layer or section without departing from the teachings of example embodiments.

Spatially relative terms, such as “beneath,” “below,” “lower,” “above,” “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the exemplary term “below” can encompass both an orientation of above and below. The device may be otherwise oriented (rotated 90 degrees or at other orientations) and the spatially relative descriptors used herein interpreted accordingly.

The terminology used herein is for the purpose of describing particular embodiments only and is not intended to be limiting of example embodiments. As used herein, the singular forms “a,” “an” and “the” are intended to include the plural forms as well, unless the context clearly indicates otherwise. It will be further understood that the terms “comprises”, “comprising”, “includes” and/or “including,” if used herein, specify the presence of stated features, integers, steps, operations, elements and/or components, but do not preclude the presence or addition of one or more other features, integers, steps, operations, elements, components and/or groups thereof.

Example embodiments of the inventive concepts are described herein with reference to cross-sectional illustrations that are schematic illustrations of idealized embodiments (and intermediate structures) of example embodiments. As such, variations from the shapes of the illustrations as a result, for example, of manufacturing techniques and/or tolerances, are to be expected. Thus, example embodiments of the inventive concepts should not be construed as limited to the particular shapes of regions illustrated herein but are to include deviations in shapes that result, for example, from manufacturing. For example, an implanted region illustrated as a rectangle may have rounded or curved features and/or a gradient of implant concentration at its edges rather than a binary change from implanted to non-implanted region. Likewise, a buried region formed by implantation may result in some implantation in the region between the buried region and the surface through which the implantation takes place. Thus, the regions illustrated in the figures are schematic in nature and their shapes are not intended to illustrate the actual shape of a region of a device and are not intended to limit the scope of example embodiments.

As appreciated by the present inventive entity, devices and methods of forming devices according to various embodiments described herein may be embodied in microelectronic devices such as integrated circuits, wherein a plurality of devices according to various embodiments described herein are integrated in the same microelectronic device. Accordingly, the cross-sectional view(s) illustrated herein may be replicated in two different directions, which need not be orthogonal, in the microelectronic device. Thus, a plan view of the microelectronic device that embodies devices according to various embodiments described herein may include a plurality of the devices in an array and/or in a two-dimensional pattern that is based on the functionality of the microelectronic device.

The devices according to various embodiments described herein may be interspersed among other devices depending on the functionality of the microelectronic device. Moreover, microelectronic devices according to various embodiments described herein may be replicated in a third direction that may be orthogonal to the two different directions, to provide three-dimensional integrated circuits.

Accordingly, the cross-sectional view(s) illustrated herein provide support for a plurality of devices according to various embodiments described herein that extend along two different directions in a plan view and/or in three different directions in a perspective view. For example, when a single active region is illustrated in a cross-sectional view of a device/structure, the device/structure may include a plurality of active regions and transistor structures (or memory cell structures, gate structures, etc., as appropriate to the case) thereon, as would be illustrated by a plan view of the device/structure.

Unless otherwise defined, all terms (including technical and scientific terms) used herein have the same meaning as commonly understood by one of ordinary skill in the art to which example embodiments of the inventive concepts belong. It will be further understood that terms, such as those defined in commonly-used dictionaries, should be interpreted as having a meaning that is consistent with their meaning in the context of the relevant art and this specification and will not be interpreted in an idealized or overly formal sense unless expressly so defined herein.

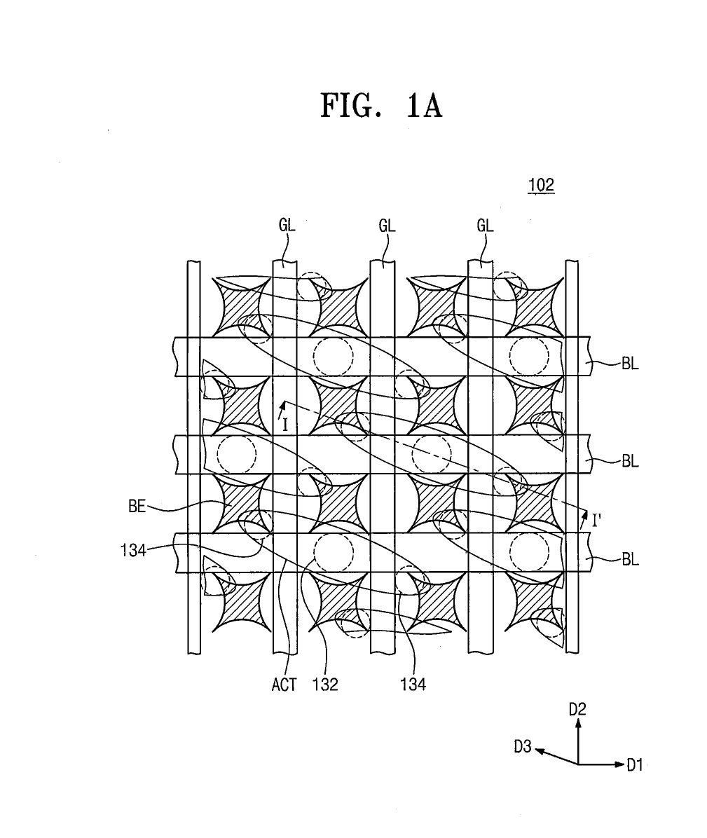

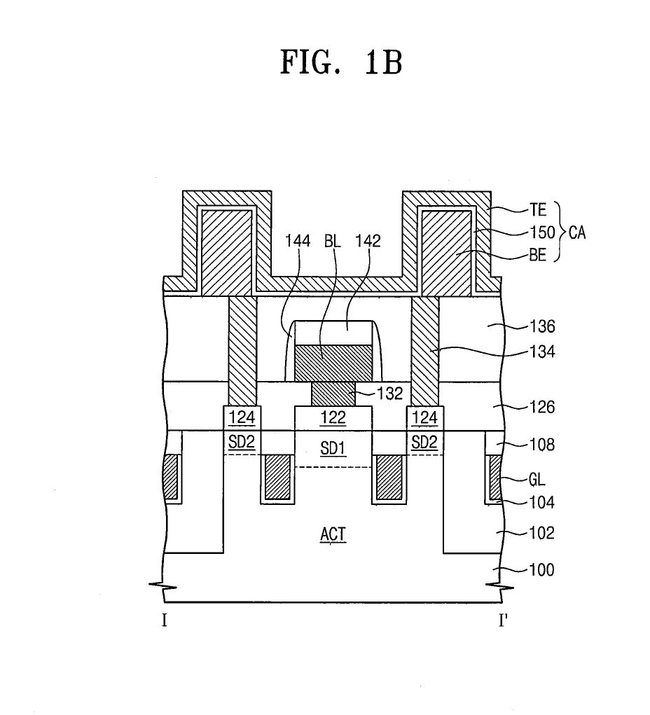

FIG. 1A is a plan view illustrating a semiconductor device according to an embodiment of the inventive concept, and FIG. 1B is a sectional view taken along line I-I′ of FIG. 1A.

Referring to FIGS. 1A and 1B, a device isolation layer 102 may be provided on a substrate 100 to define active regions ACT. The substrate 100 may be a semiconductor substrate (e.g., a silicon wafer, a germanium wafer, or a silicon-germanium wafer). The device isolation layer 102 may be formed of or include, for example, a silicon oxide layer, a silicon nitride layer, and/or a silicon oxynitride layer. When viewed in a plan view, each of the active regions ACT may be shaped like a bar, whose longitudinal axis is parallel to a third direction D3 or is at an angle to first and second directions D1 and D2 crossing each other.

Gate lines GL may be provided in the substrate 100 to cross the active regions ACT. The gate lines GL may extend parallel to the second direction D2 and may be arranged in the first direction D1. The gate lines GL may be buried in the substrate 100. The gate lines GL may include a conductive material. As an example, the gate lines GL may be formed of or include, at least one of doped semiconductor materials (e.g., doped silicon, doped germanium, etc.), conductive metal nitrides (e.g., titanium nitride, tantalum nitride, etc.), metals (e.g., tungsten, titanium, tantalum, and so forth), or metal-semiconductor compounds (e.g., tungsten silicide, cobalt silicide, titanium silicide, etc.).

Gate insulating patterns 104 may be interposed between the gate lines GL and the active regions ACT and between the gate lines GL and the device isolation layer 102. The gate insulating patterns 104 may be formed of or include, for example, at least one of a silicon oxide layer, a silicon nitride layer, and/or a silicon oxynitride layer.

First capping patterns 108 may be provided on top surfaces of the gate lines GL, respectively. Each of the first capping patterns 108 may have a top surface that is substantially coplanar with that of the substrate 100. The first capping patterns 108 may be formed of or include, for example, at least one of a silicon oxide layer, a silicon nitride layer, and/or a silicon oxynitride layer. In example embodiments, each of the first capping patterns 108 may have a bottom surface in contact with the top surface of a corresponding one of the gate insulating patterns 104 and both side surfaces in contact with the active region ACT and/or the device isolation layer 102. In other embodiments, the gate insulating patterns 104 may include portions extending between the first capping patterns 108 and the active region ACT and/or between the first capping patterns 108 and the device isolation layer 102. In this case, the first capping patterns 108 may include a silicon nitride layer, and the gate insulating patterns 104 may include a silicon oxide layer. Here, the gate insulating patterns 104 interposed between the first capping patterns 108 and the active region ACT may serve as a buffer layer relieving stress between the active region ACT and the first capping patterns.

A first doped region SD1 and second doped regions SD2 may be provided in each of the active regions ACT, and here, the second doped regions SD2 may be spaced apart from each other by the first doped region SD1. The first doped region SD1 may be provided in a portion of the active region ACT that is positioned between an adjacent pair of the gate lines GL. The second doped regions SD2 may be provided in end portions of the active region ACT that are spaced apart from each other by the pair of gate lines GL. In other words, the second doped regions SD2 may be spaced apart from each other with the pair of gate lines GL interposed therebetween. The first doped region SD1 may have a depth greater than that of the second doped regions SD2, when measured from the top surface of the substrate 100. The first doped region SD1 may be doped to have the same conductivity type as the second doped region SD2.

A first pad 122 and second pads 124 may be provided on the substrate 100. The first pad 122 may be connected to the first doped region SD1, and the second pads 124 may be connected to the second doped regions SD2, respectively. The first pad 122 and the second pads 124 may include a conductive layer (e.g., a doped poly-silicon layer and/or a doped single crystalline silicon layer). A first interlayer insulating layer 126 may be provided on the substrate 100 to cover the first pad 122 and the second pads 124. The first interlayer insulating layer 126 may be formed of or include at least one of a silicon oxide layer, a silicon nitride layer, and/or a silicon oxynitride layer.

Bit lines BL may be provided on the first interlayer insulating layer 126. The bit lines BL may extend parallel to the first direction D1 and may be spaced apart from each other in the second direction D2. Each of the bit lines BL may be electrically connected to the first doped region SD1 through the first pad 122 and a bit line contact 132. The bit line contact 132 may penetrate the first interlayer insulation layer 126 and be connected to the first pad 122. The bit lines BL may be formed of or include, at least one of doped semiconductor materials (e.g., doped silicon, doped germanium, etc.), conductive metal nitrides (e.g., titanium nitride, tantalum nitride, and so forth), metals (e.g., tungsten, titanium, tantalum, etc.), or metal-semiconductor compounds (e.g., tungsten silicide, cobalt silicide, titanium silicide, etc.). The bit line contact 132 may include the same material as that of the bit lines BL.

Second capping patterns 142 may be provided on top surfaces of the bit lines BL, respectively. The second capping patterns 142 may include, for example, a silicon nitride layer, a silicon oxide layer, and/or a silicon oxynitride layer. Bit line spacers 144 may be provided on both side surfaces of each of the bit lines BL. The bit line spacers 144 may include, for example, a silicon nitride layer, a silicon oxide layer, and/or a silicon oxynitride layer. A second interlayer insulating layer 136 may be provided on the first interlayer insulating layer 126 to cover the bit lines BL, the second capping patterns 142, and the bit line spacers 144. The second interlayer insulating layer 136 may include, for example, a silicon oxide layer. Buried contacts 134 may be provided on the substrate 100 to penetrate the first and second interlayer insulating layers 126 and 136 and be in contact with the second pads 124, respectively. The buried contacts 134 may include a conductive material (e.g., doped silicon or a metal).

Capacitors CA may be provided on the second interlayer insulating layer 136 and may be electrically connected to the second doped regions SD2, respectively. The capacitors CA may include bottom electrodes BE, which are provided on the second interlayer insulating layer 136 and are connected to the buried contacts 134, respectively. The bottom electrodes BE may be electrically connected to the second doped regions SD2, respectively, through the buried contacts 134. As shown in FIG. 1B, each of the bottom electrodes BE may be provided to have a solid pillar shape. In other embodiments, each of the bottom electrodes BE may be shaped like a bottom-closed hollow cylinder. When viewed in a plan view, the bottom electrodes BE may be two-dimensionally arranged on the substrate 100. The arrangement and shape of the bottom electrodes BE according to the present embodiment will be described in more detail below.

The capacitor CA may further include a top electrode TE, which is provided on the second interlayer insulating layer 136 to cover the bottom electrodes BE, and a dielectric layer 150 interposed between the bottom electrodes BE and the top electrode TE. The top electrode TE may be provided to cover a plurality of the bottom electrodes BE in common; that is, it may serve as a common electrode of a DRAM device. In the case where the bottom electrodes BE has a hollow cylindrical shape, the top electrode TE may be provided to face an inner side surface of each of the bottom electrodes BE. The dielectric layer 150 may be provided to conformally cover top and side surfaces of each of the bottom electrodes BE and may include a portion extending between the top electrode TE and the second interlayer insulating layer 136.

The bottom electrode BE and the top electrode TE may include at least one of doped silicon, metals, or metal compounds. The dielectric layer 150 may be formed of or include at least one of metal oxides (e.g., HfO₂, ZrO₂, Al₂O₃, La₂O₃, Ta₂O₃ and TiO₂), perovskite dielectric materials (e.g., SrTiO₃, (Ba,Sr)TiO₃, BaTiO₃, PZT, PLZT) and may be provided in a single- or multi-layered structure.

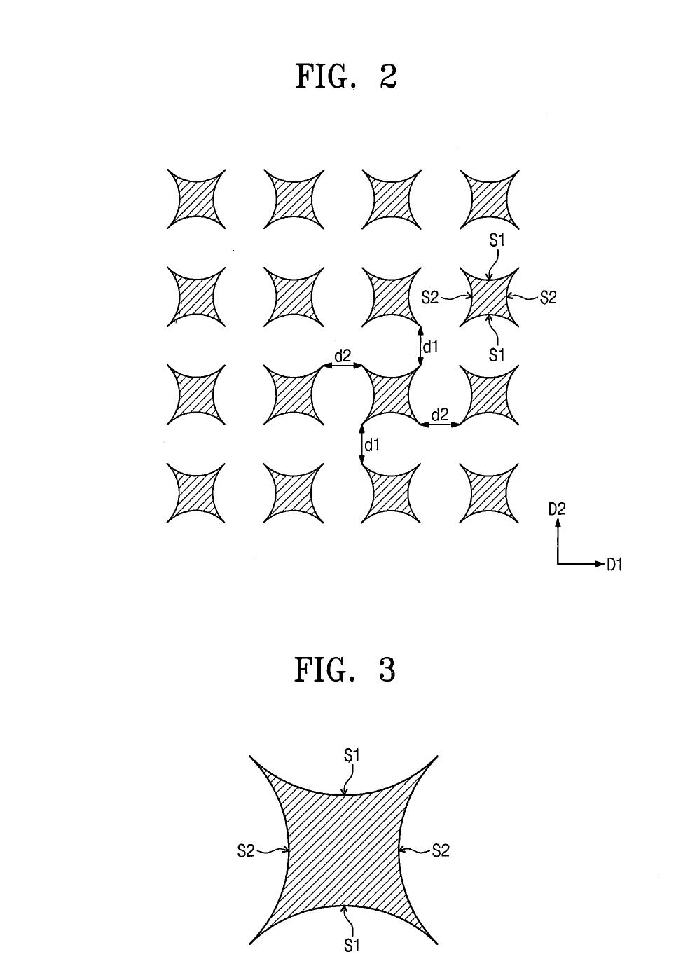

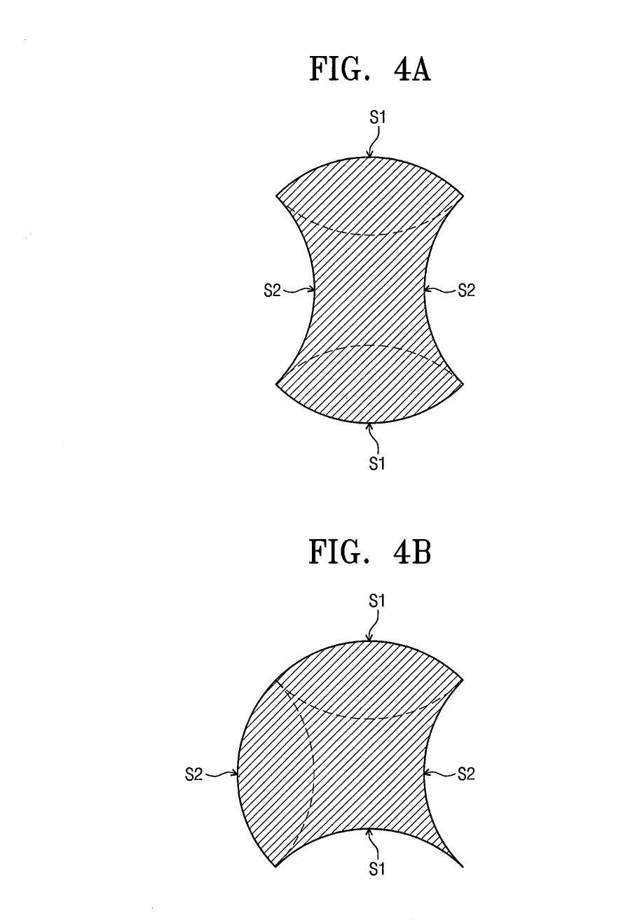

FIG. 2 is a plan view illustrating a planar arrangement of bottom electrodes provided in the semiconductor device according to an embodiment of the inventive concept, and FIG. 3 is a plan view illustrating a planar shape of each bottom electrode provided in the semiconductor device according to an embodiment of the inventive concept.

Referring to FIG. 2, the bottom electrodes BE may be arranged in both the first direction D1 and the second direction D2 to form a square arrangement, when viewed in a plan view.

Each of the bottom electrodes BE may include first side surfaces S1, which are provided to face each other, and second side surfaces S2, which are provided between the first side surfaces S1 and to face each other. The first side surfaces S1 may face each other in the second direction D2, and the second side surfaces S2 may face each other in the first direction D1. Each of the first side surfaces S1 may be spaced apart from a side surface of another bottom electrode BE adjacent thereto by a first distance d1. Each of the second side surfaces S2 may be spaced apart from a side surface of another bottom electrode BE adjacent thereto by a second distance d2. Here, the first distance d1 may be the shortest distance between the first side surface S1 and a side surface of one of the bottom electrodes BE, which is positioned most adjacent thereto in the second direction D2, and the second distance d2 may be the shortest distance between the second side surface S2 and a side surface of one of the bottom electrodes BE, which is positioned most adjacent thereto in the first direction D1. In example embodiments, the first distance d1 may be substantially equal to the second distance d2. The first and second distances d1 and d2 may be a minimum separation distance required for electrically separating the bottom electrodes BE from each other.

A pair of the bottom electrodes BE, which are positioned adjacent to the first side surfaces S1, respectively, may be disposed spaced apart from each other in the second direction D2, and another pair of the bottom electrodes BE, which are positioned adjacent to the second side surfaces S2, respectively, may be disposed spaced apart from each other in the first direction D1. The first side surfaces S1 may be disposed spaced apart from respective ones of the bottom electrodes BE paired and arranged in the second direction D2 by the first distance d1. The second side surfaces S2 may be disposed spaced apart from respective ones of the bottom electrodes BE paired and arranged in the first direction D1 by the second distance d2.

Referring to FIG. 3, when viewed in a plan view, each of the first side surfaces S1 and the second side surfaces S2 may have a concave shape. In example embodiments, when viewed in a plan view, each of the first and second side surfaces S1 and S2 may be concavely curved in a direction toward a center of the bottom electrode BE. The first side surfaces S1 may have shapes substantially symmetrical to each other, and the second side surfaces S2 may also have shapes substantially symmetrical to each other.

In general, a capacitor has capacitance that is proportional to a surface area of the bottom electrode BE. As an integration density of a semiconductor device increases, it is necessary to form a bottom electrode within a reduced planar area, and this may lead to a reduction in capacitance of the capacitor. In other words, an increase in planar area of the bottom electrode may lead to a reduction in distance between bottom electrodes, and in this case, it is difficult to electrically separate the bottom electrodes from each other. Accordingly, the increase in planar area of the bottom electrode may be limited.

According to example embodiments of the inventive concept, the bottom electrodes BE may be disposed spaced apart from each other by at least a minimum separation distance required for electrically separating the bottom electrodes BE from each other, and side surfaces of each bottom electrode BE may have a concave shape. Accordingly, it is possible to increase a surface area of each bottom electrode BE, without any deterioration in electrical separation between the bottom electrodes BE. In other words, it is possible to increase a surface area of the bottom electrode BE in a limited planar area and consequently increase electrostatic capacitance of the capacitor CA.

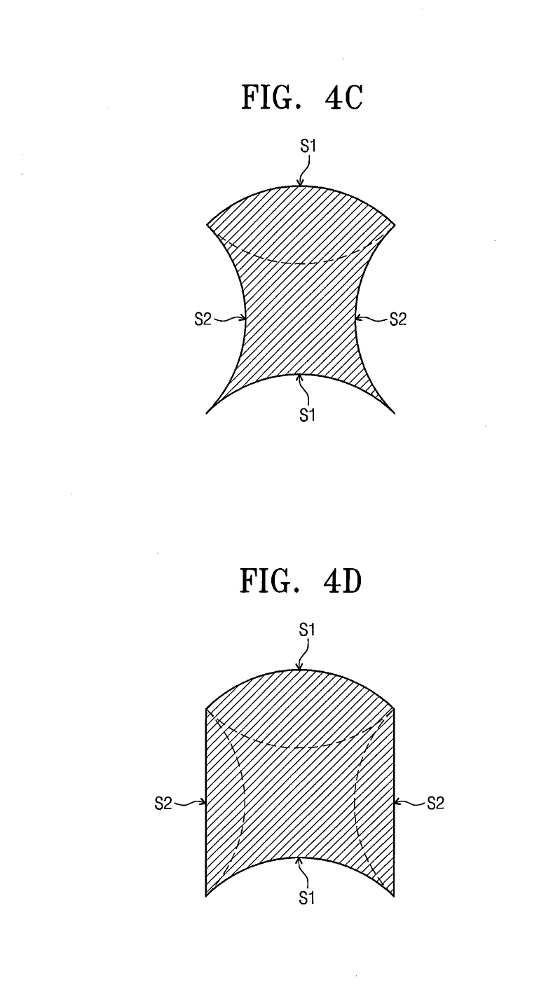

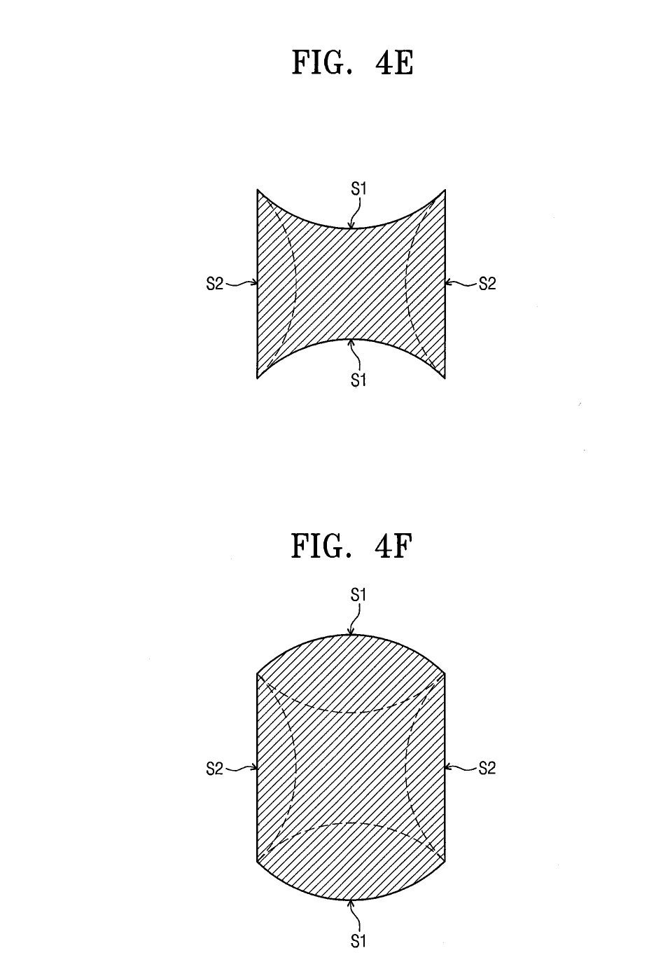

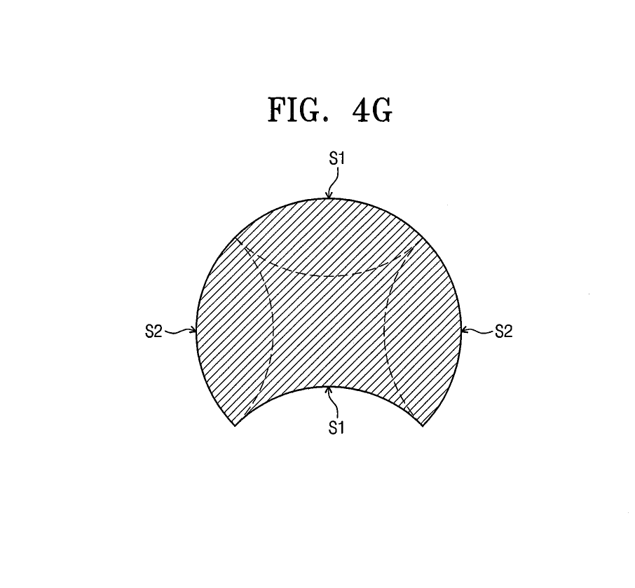

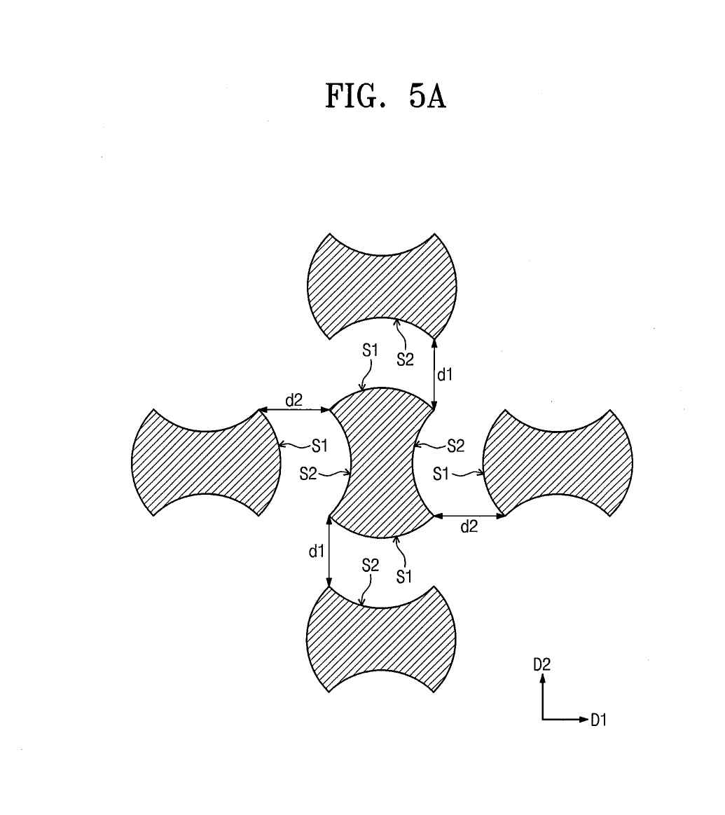

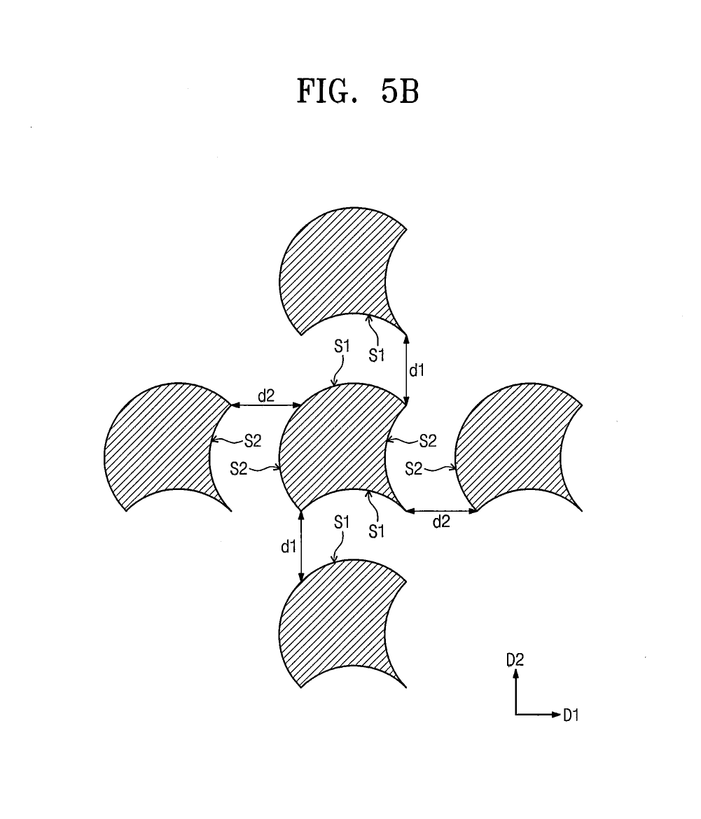

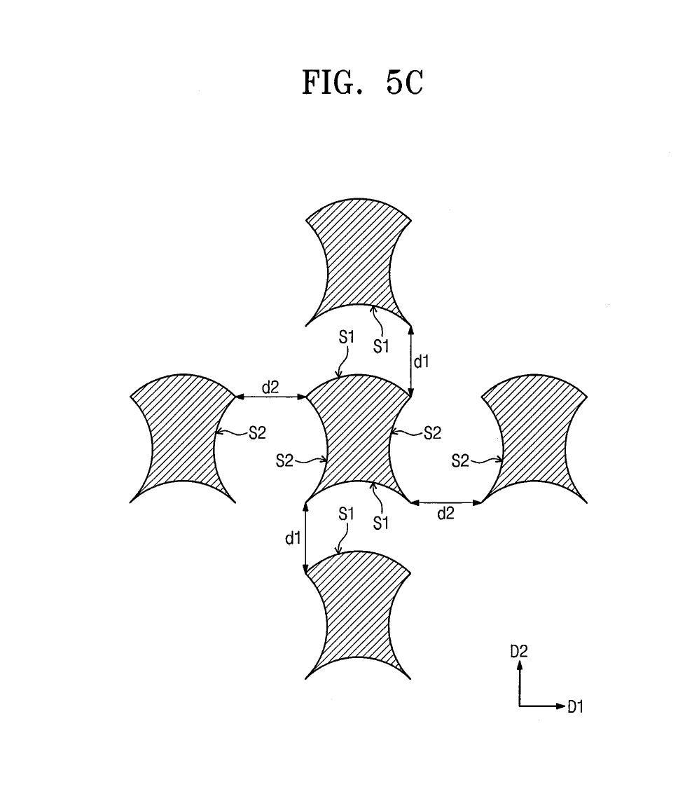

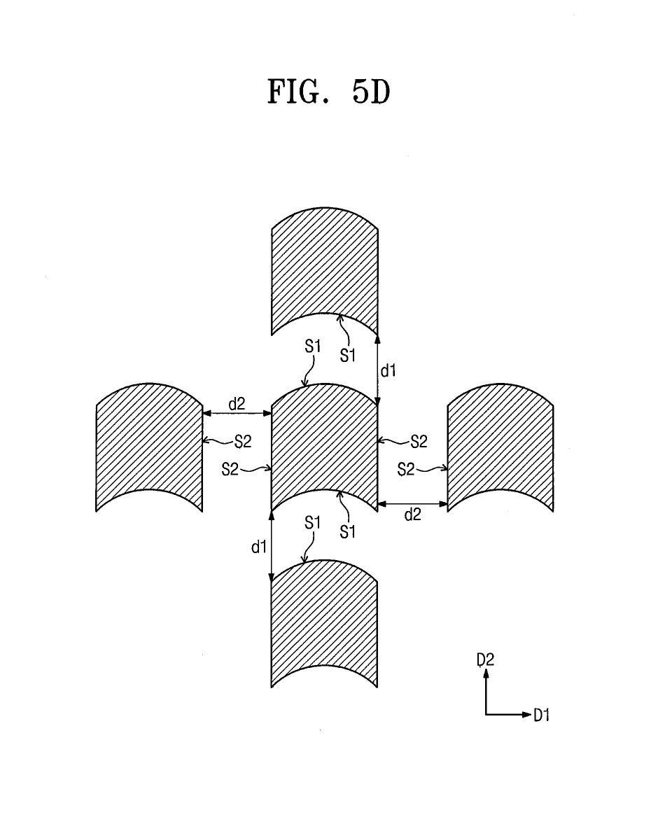

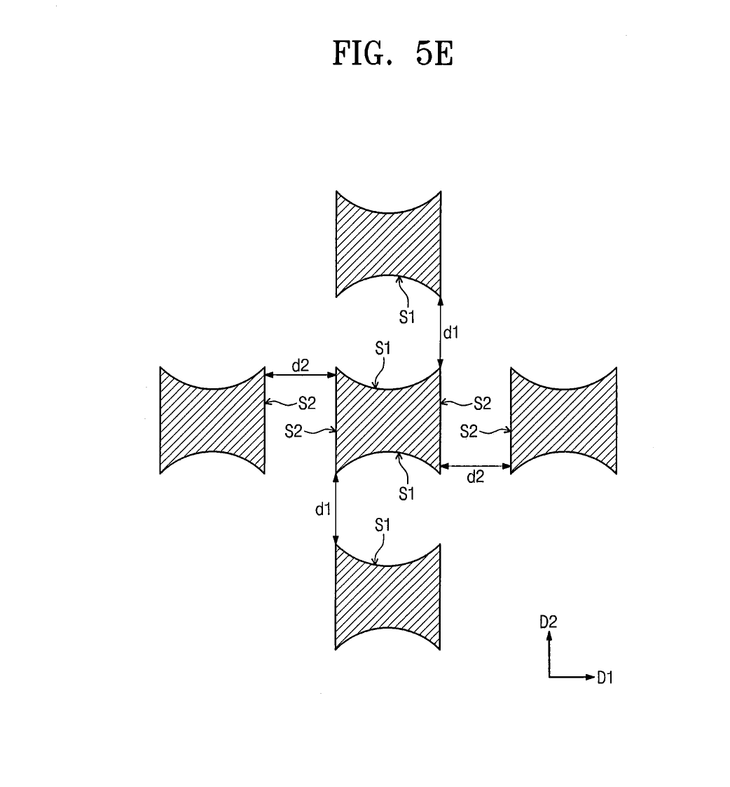

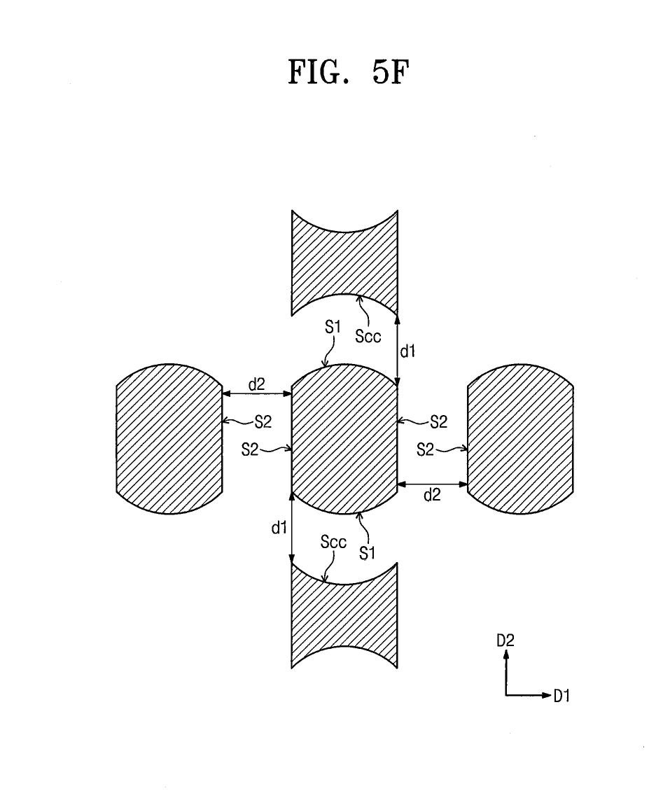

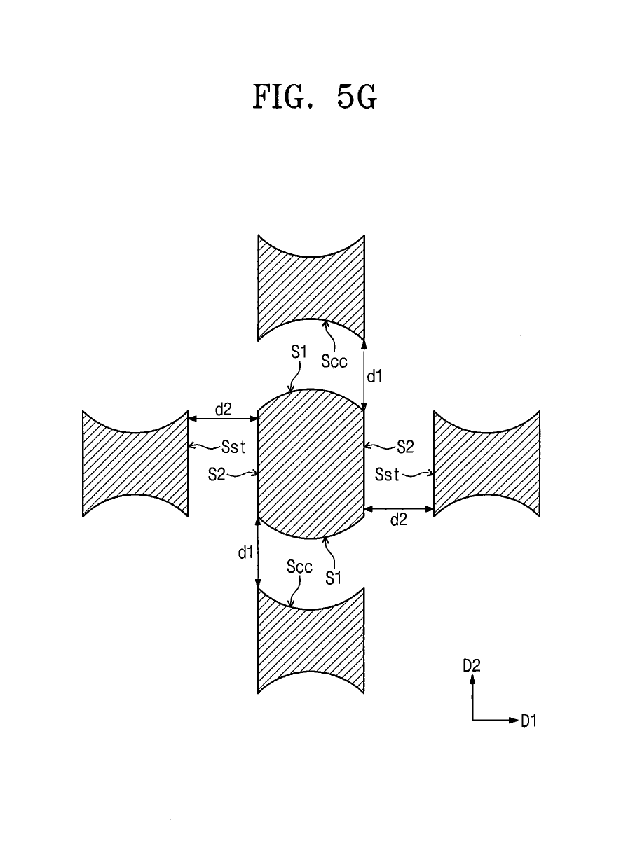

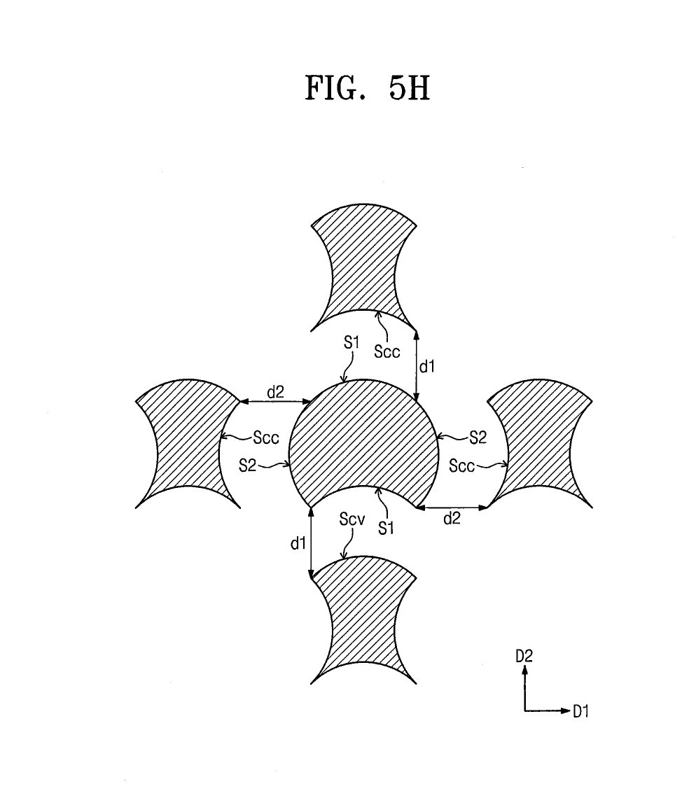

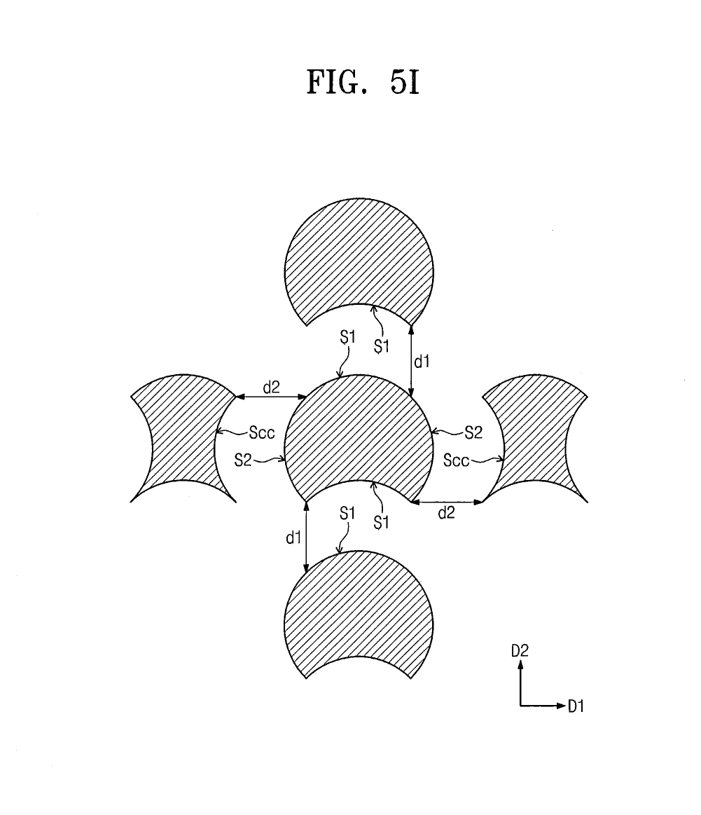

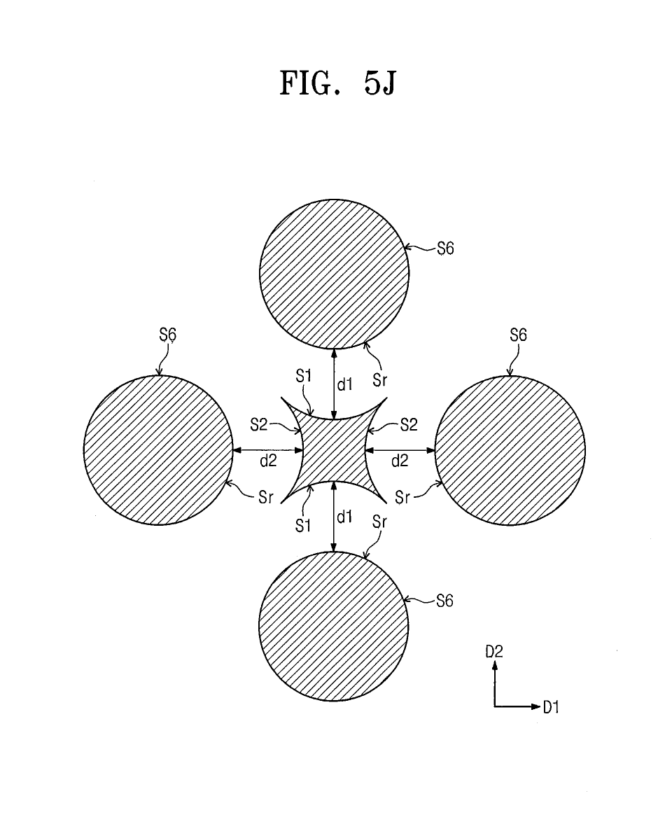

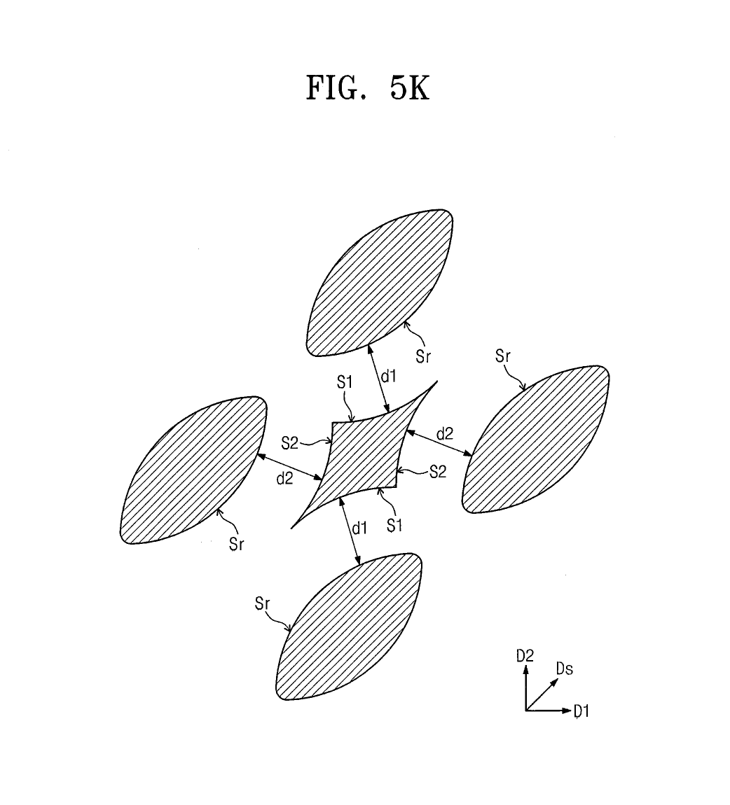

FIGS. 4A through 4G are plan views illustrating modified planar shapes of each bottom electrode provided in the semiconductor device according to an embodiment of the inventive concept, and FIGS. 5A through 5K are plan views, each of which illustrates a modified planar arrangement of the bottom electrodes provided in the semiconductor device according to an embodiment of the inventive concept.

Referring to FIG. 4A, when viewed in a plan view, each of the first side surfaces S1 may have a convex shape, whereas each of the second side surfaces S2 may have a concave shape. In example embodiments, when viewed in a plan view, the first side surfaces S1 may be convexly curved in a direction away from a center of the bottom electrode BE, whereas the second side surfaces S2 may be concavely curved in a direction toward the center of the bottom electrode BE. The first side surfaces S1 may have shapes substantially symmetrical to each other, and the second side surfaces S2 may also have shapes substantially symmetrical to each other.

In the case where each of the bottom electrodes BE has the shape of FIG. 4A, the bottom electrodes BE may be disposed to form an arrangement shown in FIG. 5A. Referring to FIG. 5A, a pair of the bottom electrodes BE, which are positioned adjacent to the first side surfaces S1, respectively, may be disposed spaced apart from each other in the second direction D2, and another pair of the bottom electrodes BE, which are positioned adjacent to the second side surfaces S2, respectively, may be disposed spaced apart from each other in the first direction D1. The first side surfaces S1 may be disposed to face respective second side surfaces S2 of the pair of the bottom electrodes BE paired and arranged in the second direction D2. Further, the second side surfaces S2 may be disposed to face respective first side surfaces S1 of the pair of the bottom electrodes BE paired and arranged in the first direction D1. In other words, a convex side surface of one of a pair of the bottom electrodes BE, which are positioned adjacent to each other, may be disposed to face a concave side surface of the other of the pair of the bottom electrodes BE. Accordingly, the first side surfaces S1 may be disposed equidistant apart from respective ones of the bottom electrodes BE paired and arranged in the second direction D2 by the first distance d1. Further, the second side surfaces S2 may be disposed equidistant apart from respective ones of the bottom electrodes BE paired and arranged in the first direction D1 by the second distance d2.

Referring to FIG. 4B, when viewed in a plan view, the first side surfaces S1 may have shapes substantially asymmetrical to each other, and the second side surfaces S2 may also have shapes substantially asymmetrical to each other. For example, one of the first side surfaces S1 may have a convex shape, and the other of the first side surfaces S1 may have a concave shape. Further, one of the second side surfaces S2 may have a convex shape, and the other of the second side surfaces S2 may have a concave shape. In example embodiments, when viewed in a plan view, one of the first side surfaces S1 and one of the second side surfaces S2 may be convexly curved in a direction away from a center of the bottom electrode BE, while the other of the first side surfaces S1 and the other of the second side surfaces S2 may be concavely curved in a direction toward a center of the bottom electrode BE.

In the case where each of the bottom electrodes BE has the shape of FIG. 4B, the bottom electrodes BE may be disposed to form an arrangement shown in FIG. 5B. Referring to FIG. 5B, a pair of the bottom electrodes BE, which are positioned adjacent to the first side surfaces S1, respectively, may be disposed spaced apart from each other in the second direction D2, and another pair of the bottom electrodes BE, which are positioned adjacent to the second side surfaces S2, respectively, may be disposed spaced apart from each other in the first direction D1. A convexly-curved one of the first side surfaces S1 may be disposed to face a concavely-curved one of the first side surfaces S1 of a neighboring one of the bottom electrodes BE, while a concavely-curved one of the first side surfaces S1 may be disposed to face a convexly-curved one of the first side surfaces S1 of a neighboring one of the bottom electrodes BE. Further, a convexly-curved one of the second side surfaces S2 may be disposed to face a concavely-curved one of the second side surfaces S2 of a neighboring one of the bottom electrodes BE, while a concavely-curved one of the second side surfaces S2 may be disposed to face a convexly-curved one of the second side surfaces S2 of a neighboring one of the bottom electrodes BE. In other words, a convex side surface of one of a pair of the bottom electrodes BE, which are positioned adjacent to each other, may be disposed to face a concave side surface of the other of the pair of the bottom electrodes BE. Accordingly, each of the first side surfaces S1 may be disposed equidistant apart from respective ones of the bottom electrodes BE paired and arranged in the second direction D2 by the first distance d1. Further, each of the second side surfaces S2 may be disposed equidistant apart from respective ones of the bottom electrodes BE paired and arranged in the first direction D1 by the second distance d2.

Referring to FIG. 4C, when viewed in a plan view, the first side surfaces S1 may have shapes substantially asymmetrical to each other, and the second side surfaces S2 may have shapes substantially symmetrical to each other. For example, one of the first side surfaces S1 may have a convex shape, and the other of the first side surfaces S1 may have a concave shape. The second side surfaces S2 may each have a concave shape. In example embodiments, when viewed in a plan view, one of the first side surfaces S1 may be convexly curved in a direction away from a center of the bottom electrode BE, and the other of the first side surfaces S1 may be concavely curved in a direction toward a center of the bottom electrode BE. Further, when viewed in a plan view, the second side surfaces S2 may be concavely curved in a direction toward a center of the bottom electrode BE.

In the case where each of the bottom electrodes BE has the shape of FIG. 4C, the bottom electrodes BE may be disposed to form an arrangement shown in FIG. 5C. Referring to FIG. 5C, a pair of the bottom electrodes BE, which are positioned adjacent to the first side surfaces S1, respectively, may be disposed spaced apart from each other in the second direction D2, and another pair of the bottom electrodes BE, which are positioned adjacent to the second side surfaces S2, respectively, may be disposed spaced apart from each other in the first direction D1. A convexly-curved one of the first side surfaces S1 may be disposed to face a concavely-curved one of the first side surfaces S1 of a neighboring one of the bottom electrodes BE, while a concavely-curved one of the first side surfaces S1 may be disposed to face a convexly-curved one of the first side surfaces S1 of a neighboring one of the bottom electrodes BE. In other words, a convex side surface of one of a pair of the bottom electrodes BE, which are positioned adjacent to each other, may be disposed to face a concave side surface of the other of the pair of the bottom electrodes BE. Accordingly, the first side surfaces S1 may be disposed equidistant apart from respective ones of the bottom electrodes BE paired and arranged in the second direction D2 by the first distance d1. Further, the second side surfaces S2 may be disposed to face respective second side surfaces S2 of the bottom electrodes BE paired and arranged in the first direction D1. In this case, the second side surfaces S2 may be disposed spaced apart from respective ones of the bottom electrodes BE paired and arranged in the first direction D1 by the second distance d2.

Referring to FIG. 4D, when viewed in a plan view, the first side surfaces S1 may have shapes substantially asymmetrical to each other, and the second side surfaces S2 may have shapes substantially symmetrical to each other. For example, one of the first side surfaces S1 may have a convex shape, and the other of the first side surfaces S1 may have a concave shape. The second side surfaces S2 may each have a linear shape extending straight parallel to the second direction D2. In example embodiments, when viewed in a plan view, one of the first side surfaces S1 may be convexly curved in a direction away from a center of the bottom electrode BE, and the other of the first side surfaces S1 may be concavely curved in a direction toward a center of the bottom electrode BE.

In the case where each of the bottom electrodes BE has the shape of FIG. 4D, the bottom electrodes BE may be disposed to form an arrangement shown in FIG. 5D. Referring to FIG. 5D, a pair of the bottom electrodes BE, which are positioned adjacent to the first side surfaces S1, respectively, may be disposed spaced apart from each other in the second direction D2, and another pair of the bottom electrodes BE, which are positioned adjacent to the second side surfaces S2, respectively, may be disposed spaced apart from each other in the first direction D1. A convexly-curved one of the first side surfaces S1 may be disposed to face a concavely-curved one of the first side surfaces S1 of a neighboring one of the bottom electrodes BE, while a concavely-curved one of the first side surfaces S1 may be disposed to face a convexly-curved one of the first side surfaces S1 of a neighboring one of the bottom electrodes BE. In other words, a convex side surface of one of a pair of the bottom electrodes BE, which are positioned adjacent to each other, may be disposed to face a concave side surface of the other of the pair of the bottom electrodes BE. Accordingly, the first side surfaces S1 may be disposed equidistant apart from respective ones of the bottom electrodes BE paired and arranged in the second direction D2 by the first distance d1. Further, the second side surfaces S2 may be disposed to face respective second side surfaces S2 of the bottom electrodes BE paired and arranged in the first direction D1. In this case, the second side surfaces S2 may be disposed equidistant apart from respective ones of the bottom electrodes BE paired and arranged in the first direction D1 by the second distance d2.

Referring to FIG. 4E, when viewed in a plan view, the first side surfaces S1 may have shapes substantially symmetrical to each other, and the second side surfaces S2 may also have shapes substantially symmetrical to each other. For example, the first side surfaces S1 may have a concave shape, whereas the second side surfaces S2 may have a linear shape extending straight parallel to the second direction D2. The first side surfaces S1 may be concavely curved in a direction toward a center of the bottom electrode BE, when viewed in a plan view.

In the case where each of the bottom electrodes BE has the shape of FIG. 4E, the bottom electrodes BE may be disposed to form an arrangement shown in FIG. 5E. Referring to FIG. 5E, a pair of the bottom electrodes BE, which are positioned adjacent to the first side surfaces S1, respectively, may be disposed spaced apart from each other in the second direction D2, and another pair of the bottom electrodes BE, which are positioned adjacent to the second side surfaces S2, respectively, may be disposed spaced apart from each other in the first direction D1. The first side surfaces S1 may be disposed to face respective first side surfaces S1 of the pair of the bottom electrodes BE paired and arranged in the second direction D2. In this case, the first side surfaces S1 may be disposed spaced apart from respective ones of the bottom electrodes BE paired and arranged in the second direction D2 by the first distance d1. Further, the second side surfaces S2 may be disposed to face respective second side surfaces S2 of the bottom electrodes BE paired and arranged in the first direction D1. In this case, the second side surfaces S2 may be disposed equidistant apart from respective ones of the bottom electrodes BE paired and arranged in the first direction D1 by the second distance d2.

Referring to FIG. 4F, when viewed in a plan view, the first side surfaces S1 may have shapes substantially symmetrical to each other, and the second side surfaces S2 may also have shapes substantially symmetrical to each other. For example, the first side surfaces S1 may each have a convex shape, and the second side surfaces S2 may each have a linear shape extending straight parallel to the second direction D2. When viewed in a plan view, the first side surfaces S1 may be convexly curved in a direction away from a center of the bottom electrode BE.

In the case where at least one of the bottom electrodes BE has the shape of FIG. 4F, the bottom electrodes BE may be disposed to form an arrangement shown in FIG. 5F or 5G, but example embodiments of the inventive concepts may not be limited thereto.

As an example, referring to FIG. 5F, a pair of the bottom electrodes BE, which are positioned adjacent to the first side surfaces S1, respectively, may be disposed spaced apart from each other in the second direction D2, and another pair of the bottom electrodes BE, which are positioned adjacent to the second side surfaces S2, respectively, may be disposed spaced apart from each other in the first direction D1. The pair of the bottom electrodes BE arranged in the second direction D2 may have the same shape as that of FIG. 4E. In this case, the first side surfaces S1 may be disposed to face respective concave side surfaces Scc of the pair of the bottom electrodes BE paired and arranged in the second direction D2. In other words, a convex side surface of one of a pair of the bottom electrodes BE, which are positioned adjacent to each other in the second direction D2, may be disposed to face a concave side surface of the other of the pair of the bottom electrodes BE. Accordingly, the first side surfaces S1 may be disposed equidistant apart from respective ones of the bottom electrodes BE paired and arranged in the second direction D2 by the first distance d1. Further, the pair of the bottom electrodes BE arranged in the first direction D1 may have the same shape as that of, for example, FIG. 4F. In this case, the second side surfaces S2 may be disposed to face respective second side surfaces S2 of the pair of the bottom electrodes BE paired and arranged in the first direction D1. Accordingly, the second side surfaces S2 may be disposed equidistant apart from respective ones of the bottom electrodes BE paired and arranged in the first direction D1 by the second distance d2.

As another example, referring to FIG. 5G, a pair of the bottom electrodes BE, which are positioned adjacent to the first side surfaces S1, respectively, may be disposed spaced apart from each other in the second direction D2, and another pair of the bottom electrodes BE, which are positioned adjacent to the second side surfaces S2, respectively, may be disposed spaced apart from each other in the first direction D1. The pair of the bottom electrodes BE arranged in the second direction D2 and another pair of the bottom electrodes BE arranged in the first direction D1 may have the same shape as that of, for example, FIG. 4E. In this case, the first side surfaces S1 may be disposed to face respective concave side surfaces Scc of the pair of the bottom electrodes BE paired and arranged in the second direction D2. In other words, a convex side surface of one of a pair of the bottom electrodes BE, which are positioned adjacent to each other in the second direction D2, may be disposed to face a concave side surface of the other of the pair of the bottom electrodes BE. Accordingly, the first side surfaces S1 may be disposed equidistant apart from respective ones of the bottom electrodes BE paired and arranged in the second direction D2 by the first distance d1. Further, the second side surfaces S2 may be disposed to face respective linear side surfaces Sst of the pair of the bottom electrodes BE paired and arranged in the first direction D1. Accordingly, the second side surfaces S2 may be disposed equidistant apart from respective ones of the bottom electrodes BE paired and arranged in the first direction D1 by the second distance d2.

Referring to FIG. 4G, the first side surfaces S1 may have shapes substantially asymmetrical to each other, and the second side surfaces S2 may have shapes substantially symmetrical to each other. For example, one of the first side surfaces S1 may have a convex shape, and the other of the first side surfaces S1 may have a concave shape. The second side surfaces S2 may each have a convex shape. In example embodiments, one of the first side surfaces S1 and the second side surfaces S2 may be convexly curved in a direction away from a center of the bottom electrode BE, and the other of the first side surfaces S1 may be concavely curved in a direction toward a center of the bottom electrode BE, when viewed in a plan view.

In the case where at least one of the bottom electrodes BE has the shape of FIG. 4G, the bottom electrodes BE may be disposed to form an arrangement shown in FIG. 5H or 5I, but example embodiments of the inventive concepts may not be limited thereto.

As an example, as shown in FIG. 5H, a pair of the bottom electrodes BE, which are positioned adjacent to the first side surfaces S1, respectively, may be disposed spaced apart from each other in the second direction D2, and another pair of the bottom electrodes BE, which are positioned adjacent to the second side surfaces S2, respectively, may be disposed spaced apart from each other in the first direction D1. The pair of the bottom electrodes BE arranged in the second direction D2 and another pair of the bottom electrodes BE arranged in the first direction D1 may have the same shape as that of, for example, FIG. 4C. In this case, a convexly-curved one of the first side surfaces S1 may be disposed to face a concave side surface Scc of a neighboring one of the bottom electrodes BE, while a concavely-curved one of the first side surfaces S1 may be disposed to face a convex side surface Scv of a neighboring one of the bottom electrodes BE. Further, the second side surfaces S2 may be disposed to face respective concave side surfaces Scc of the pair of the bottom electrodes BE paired and arranged in the first direction D1. In other words, a convex side surface of one of a pair of the bottom electrodes BE, which are positioned adjacent to each other, may be disposed to face a concave side surface of the other of the pair of the bottom electrodes BE. Accordingly, the first side surfaces S1 may be disposed equidistant apart from respective ones of the bottom electrodes BE paired and arranged in the second direction D2 by the first distance d1, and the second side surfaces S2 may be disposed equidistant apart from respective ones of the bottom electrodes BE paired and arranged in the first direction D1 by the second distance d2.

As another example, as shown in FIG. 5I, a pair of the bottom electrodes BE, which are positioned adjacent to the first side surfaces S1, respectively, may be disposed spaced apart from each other in the second direction D2, and another pair of the bottom electrodes BE, which are positioned adjacent to the second side surfaces S2, respectively, may be disposed spaced apart from each other in the first direction D1. The pair of the bottom electrodes BE arranged in the second direction D2 may have the same shape as that of, for example, FIG. 4G. In this case, a convexly-curved one of the first side surfaces S1 may be disposed to face a concavely-curved one of the first side surfaces S1 of a neighboring one of the bottom electrodes BE, and a concavely-curved one of the first side surfaces S1 may be disposed to face a convexly-curved one of the first side surfaces S1 of a neighboring one of the bottom electrodes BE. Accordingly, the first side surfaces S1 may be disposed equidistant apart from respective ones of the bottom electrodes BE paired and arranged in the second direction D2 by the first distance d1. Further, the pair of the bottom electrodes BE arranged in the first direction D1 may have the same shape as that of, for example, FIG. 4C. In this case, the second side surfaces S2 may be disposed to face respective concave side surfaces Scc of the pair of the bottom electrodes BE paired and arranged in the first direction D1. Accordingly, the second side surfaces S2 may be disposed equidistant apart from respective ones of the bottom electrodes BE paired and arranged in the first direction D1 by the second distance d2.

In the case where at least one of the bottom electrodes BE has the shape of FIG. 3, the bottom electrodes BE may be disposed to form an arrangement shown in FIG. 5J, but example embodiments of the inventive concepts may not be limited thereto.

As an example, referring to FIG. 5J, a pair of the bottom electrodes BE, which are positioned adjacent to the first side surfaces S1, respectively, may be disposed spaced apart from each other in the second direction D2, and another pair of the bottom electrodes BE, which are positioned adjacent to the second side surfaces S2, respectively, may be disposed spaced apart from each other in the first direction D1. The pair of the bottom electrodes BE arranged in the second direction D2 and another pair of the bottom electrodes BE arranged in the first direction D1 may have a circular shape. In this case, the first side surfaces S1 may be disposed to face respective rounded side surfaces Sr of the pair of the bottom electrodes BE paired and arranged in the second direction D2, and the second side surfaces S2 may be disposed to face respective rounded side surfaces Sr of the pair of the bottom electrodes BE paired and arranged in the first direction D1. Accordingly, the first side surfaces S1 may be disposed equidistant apart from respective ones of the bottom electrodes BE paired and arranged in the second direction D2 by the first distance d1, and the second side surfaces S2 may be disposed equidistant apart from respective ones of the bottom electrodes BE paired and arranged in the first direction D1 by the second distance d2.

In the case where at least one of the bottom electrodes BE has a shape similar to FIG. 3, the bottom electrodes BE may be disposed to form an arrangement shown in FIG. 5K, but example embodiments of the inventive concepts may not be limited thereto. Here, as an example of the shape similar to FIG. 3, the shape of FIG. 3 may be changed in such a way that its longitudinal axis is parallel to a diagonal direction Ds or at an angle to both the first and second directions D1 and D2.

As an example, referring to FIG. 5K, a pair of the bottom electrodes BE, which are positioned adjacent to the first side surfaces S1, respectively, may be disposed spaced apart from each other in the second direction D2, and another pair of the bottom electrodes BE, which are positioned adjacent to the second side surfaces S2, respectively, may be disposed spaced apart from each other in the first direction D1. The pair of the bottom electrodes BE arranged in the second direction D2 and another pair of the bottom electrodes BE arranged in the first direction D1 may be shaped like, for example, an ellipse, whose major axis is parallel to the diagonal direction Ds. In this case, the first side surfaces S1 may be disposed to face respective rounded side surfaces Sr of the pair of the bottom electrodes BE paired and arranged in the second direction D2, and the second side surfaces S2 may be disposed to face respective rounded side surfaces Sr of the pair of the bottom electrodes BE paired and arranged in the first direction D1. The first side surfaces S1 may be disposed equidistant apart from respective ones of the bottom electrodes BE paired and arranged in the second direction D2 by the first distance d1, and the second side surfaces S2 may be disposed equidistant apart from respective ones of the bottom electrodes BE paired and arranged in the first direction D1 by the second distance d2.

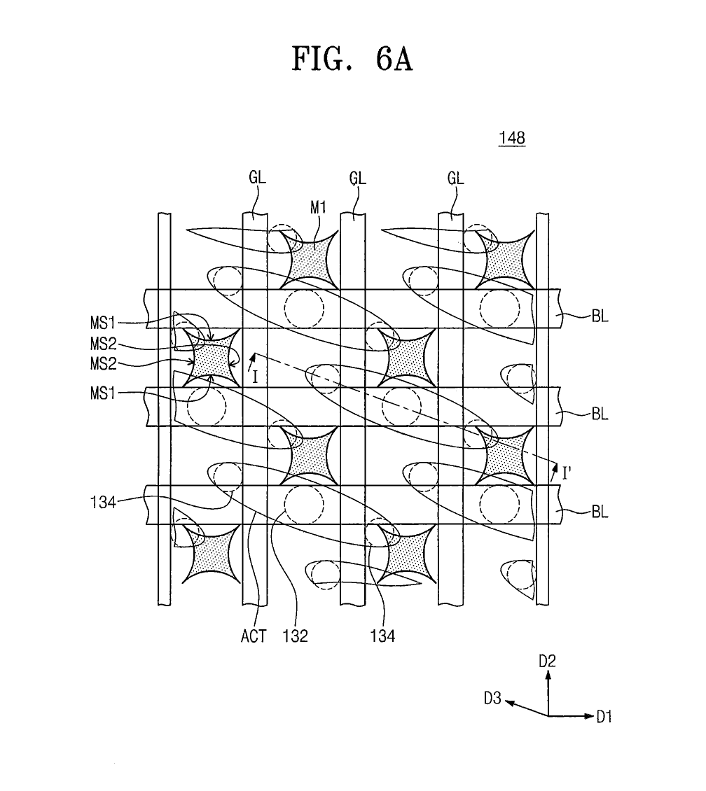

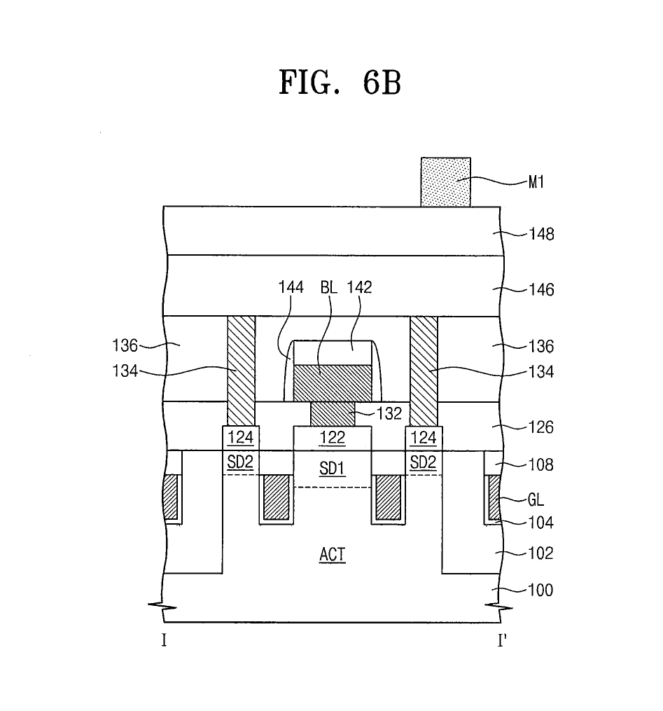

FIGS. 6A through 11A are plan views illustrating a method of fabricating a semiconductor device, according to an embodiment of the inventive concept, and FIGS. 6B through 11B are sectional views taken along lines I-I′ of FIGS. 6A through 11A, respectively.

Referring to FIGS. 6A and 6B, a device isolation layer 102 may be formed on a substrate 100 to define active regions ACT. The substrate 100 may be a semiconductor substrate (e.g., a silicon wafer, a germanium wafer, or a silicon-germanium wafer). The device isolation layer 102 may be formed using, for example, a shallow trench isolation (STI) process. The device isolation layer 102 may be formed of or include, for example, a silicon nitride layer, a silicon oxide layer, and/or a silicon oxynitride layer. Each of the active regions ACT may be shaped like a bar elongated in a third direction D3. For example, a longitudinal axis of each active region ACT may be parallel to the third direction D3, which is at an angle to two orthogonal directions (for example, first and second directions D1 and D2).

Second doped regions SD2 may be formed in each of the active regions ACT. The second doped regions SD2 may be formed by an ion implantation process. As an example, the second doped regions SD2 may be an n-type doped region.

Gate lines GL may be formed in the substrate 100 to cross the active regions ACT. The gate lines GL may extend parallel to the second direction D2 and may be formed spaced apart from each other in the first direction D1. Gate insulating patterns 104 may be formed between the gate lines GL and the active regions ACT and between the gate lines GL and the device isolation layer 102. First capping patterns 108 may be formed on top surfaces of the gate lines GL, respectively. The formation of the gate lines GL and the gate insulating patterns 104 may include etching the substrate 100 and the device isolation layer 102 to form line-shaped trenches extending parallel to the second direction D2, forming a gate insulating layer on the substrate 100 to partially fill each of the trenches, forming a conductive layer on the substrate 100 to fill the remaining spaces of the trenches, and etching the conductive layer to form a conductive pattern with a desired thickness in each of the trenches. The etching process may be performed to remove an exposed portion of the insulating layer, which is not covered with the conductive layer, and thereby to form the gate insulating patterns 104 in the trenches, respectively. The formation of the first capping patterns 108 may include forming a first capping layer on the substrate 100 provided with the gate lines GL and planarizing the first capping layer to expose the top surface of the substrate 100.

An ion implantation process may be performed to form a first doped region SD1 in a portion of each active region ACT positioned between an adjacent pair of the gate lines GL. The first doped region SD1 may be doped to have the same conductivity type (e.g., n-type) as that of the second doped regions SD2. The first doped region SD1 may be formed to have a depth greater than that of the second doped regions SD2, when measured from a top surface of the substrate 100.

A doped poly-silicon layer, a doped single crystalline silicon layer, or a conductive layer may be formed on the substrate 100 and then may be patterned to form a first pad 122 and second pads 124. The first pad 122 may be connected to the first doped region SD1, and the second pads 124 may be connected to the second doped regions SD2, respectively. In the case where the first pad 122 and the second pads 124 include a doped poly-silicon layer or a single crystalline silicon layer, the first pad 122 and the second pads 124 may be doped to have the same conductivity type as the first and second doped regions SD1 and SD2.

A first interlayer insulating layer 126 may be formed on the first and second pads 122 and 124. The first interlayer insulating layer 126 may be formed by a chemical vapor deposition process. The first interlayer insulating layer 126 may include, for example, a silicon oxide layer, a silicon nitride layer, or a silicon oxynitride layer. A bit line contact hole may be formed to penetrate the first interlayer insulating layer 126 and expose the first pad 122. A second conductive layer may be formed on the first interlayer insulating layer 126. The second conductive layer may be formed to fill the bit line contact hole. For example, the second conductive layer may include a conductive material (e.g., metals and doped semiconductor materials). A second capping layer may be formed on the second conductive layer. As an example, the second capping layer may include at least one of a silicon nitride layer, a silicon oxide layer, and a silicon oxynitride layer. The second capping layer and the second conductive layer may be patterned to form a bit line BL and a second capping pattern 142 on the bit line BL. A bit line contact 132 may be formed in the bit line contact hole. A spacer layer may be conformally deposited on the first interlayer insulating layer 126 and then may be anisotropically etched to form bit line spacers 144 covering both side surfaces of the bit line BL. The bit line spacers 144 may be formed of or include at least one of a silicon nitride layer, a silicon oxide layer, or a silicon oxynitride layer.

A second interlayer insulating layer 136 may be formed on the first interlayer insulating layer 126. The second interlayer insulating layer 136 may be formed using, for example, a chemical vapor deposition process. The second interlayer insulating layer 136 may include a silicon oxide layer, a silicon nitride layer, or a silicon oxynitride layer. Buried contact holes may be formed to penetrate the second interlayer insulating layer 136 and the first interlayer insulating layer 126 and expose the second pads 124, respectively. A third conductive layer may be deposited on the second interlayer insulating layer 136 to fill the buried contact holes and may be planarized to expose a top surface of the second interlayer insulating layer 136. Accordingly, buried contacts 134 may be formed in the buried contact holes, respectively.

A first mold layer 146 and a lower mask layer 148 may be sequentially formed on the second interlayer insulating layer 136. The lower mask layer 148 may be formed of a material having an etch selectivity with respect to the first mold layer 146. For example, the first mold layer 146 may be formed of a crystalline silicon layer, an amorphous silicon layer, a doped silicon layer, a silicon germanium layer, or a carbon-based layer, and the lower mask layer 148 may be formed of a silicon oxide layer.

First mask patterns M1 may be formed on the lower mask layer 148. The first mask patterns M1 may be formed of a material having an etch selectivity with respect to the lower mask layer 148. For example, the first mask patterns M1 may be formed of a silicon nitride layer and/or a silicon oxynitride layer. When viewed in a plan view, the first mask patterns M1 may be arranged in the first direction D1 and the second direction D2 to form a plurality of rows and a plurality of columns. N-th ones of the first mask patterns M1 constituting odd-numbered rows may form a first column, and n-th ones of the first mask patterns M1 constituting even-numbered rows may form a second column adjacent to the first column, where n is an integer. When viewed in a plan view, the first mask patterns M1 constituting the first column and the second column may be arranged in a zigzag manner. When viewed in a plan view, the first mask patterns M1 may be formed in such a way that each of them is at least partially overlapped with a corresponding one of the buried contacts 134.

Each of the first mask patterns M1 may include first mask side surfaces MS1, which are provided to face each other, and second mask side surfaces MS2, which are provided between the first mask side surfaces MS1 to face each other. The first mask side surfaces MS1 may face each other in the second direction D2, and the second mask side surfaces MS2 may face each other in the first direction D1. In example embodiments, when viewed in a plan view, each of the first and second mask side surfaces MS1 and MS2 may have a concave shape. As an example, each of the first and second mask side surfaces MS1 and MS2 may be concavely curved in a direction toward a center of the first mask pattern M1. However, in certain embodiments, when viewed in a plan view, at least one of the first and second mask side surfaces MS1 and MS2 may have a convex or linear shape. For example, at least one of the first and second mask side surfaces MS1 and MS2 may be convexly curved in a direction away from a center of the first mask pattern M1 or may have a linear shape extending parallel to a specific direction.

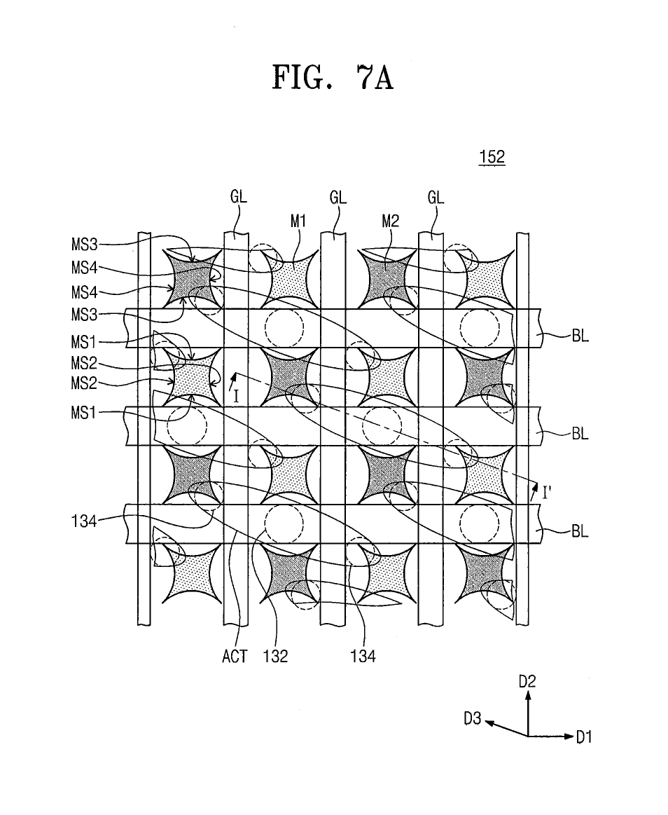

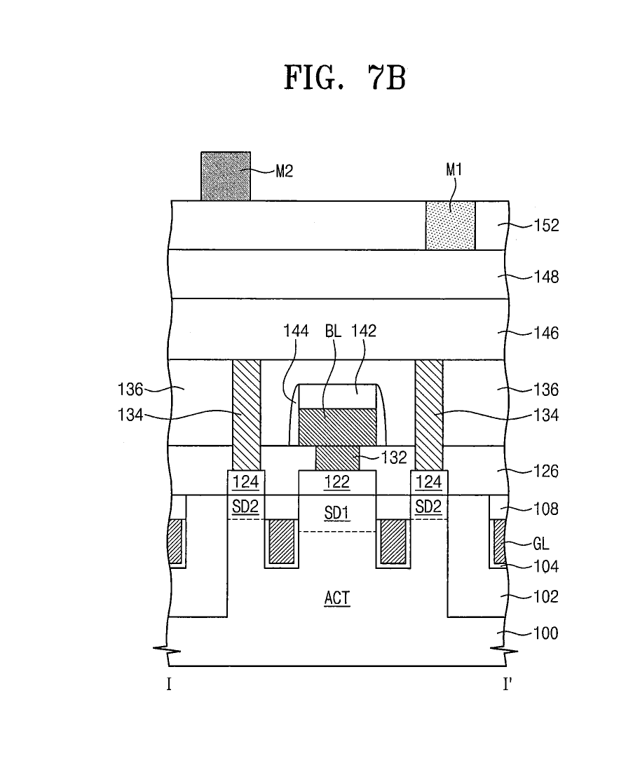

Referring to FIGS. 7A and 7B, an upper mask layer 152 may be formed on the lower mask layer 148 to cover the first mask patterns M1. The upper mask layer 152 may be formed of, for example, a silicon oxide layer.

Second mask patterns M2 may be formed on the upper mask layer 152. The second mask patterns M2 may be formed of, for example, a silicon nitride layer and/or a silicon oxynitride layer. When viewed in a plan view, the second mask patterns M2 may be arranged in the first direction D1 and the second direction D2 to form a plurality of rows and a plurality of columns. N-th ones of the second mask patterns M2 constituting odd-numbered rows may form a first column, and n-th ones of the second mask patterns M2 constituting even-numbered rows may form a second column adjacent to the first column, where n is an integer. When viewed in a plan view, the second mask patterns M2 constituting the first column and the second column may be arranged in a zigzag manner. When viewed in a plan view, the second mask patterns M2 may be formed spaced apart from the first mask patterns M1. The second mask patterns M2 may be formed on the upper mask layer 152 in such a way that each of them is placed on a position between a pair of the first mask patterns M1 adjacent to each other in the first direction D1 and between another pair of the first mask patterns M1 adjacent to each other in the second direction D2. When viewed in a plan view, the second mask patterns M2 may be formed in such a way that each of them is at least partially overlapped with a corresponding one of the buried contacts 134.

Each of the second mask patterns M2 may include third mask side surfaces MS3, which are provided to face each other, and fourth mask side surfaces MS4, which are provided between the third mask side surfaces MS3 to face each other. The third mask side surfaces MS3 may face each other in the second direction D2, and the fourth mask side surfaces MS4 may face each other in the first direction D1. In example embodiments, when viewed in a plan view, each of the third and fourth mask side surfaces MS3 and MS4 may have a concave shape. As an example, each of the third and fourth mask side surfaces MS3 and MS4 may be concavely curved in a direction toward a center of the second mask pattern M2. However, in certain embodiments, when viewed in a plan view, at least one of the third and fourth mask side surfaces MS3 and MS4 may have a convex or linear shape. As an example, at least one of the third and fourth mask side surfaces MS3 and MS4 may be convexly curved in a direction away from a center of the second mask pattern M2 or may have a linear shape extending parallel to a specific direction.

In example embodiments, the first and second mask patterns M1 and M2 may have substantially the same shape, but in other example embodiments, at least one of the first and second mask patterns M1 and M2 may be formed to have a different shape from the others.

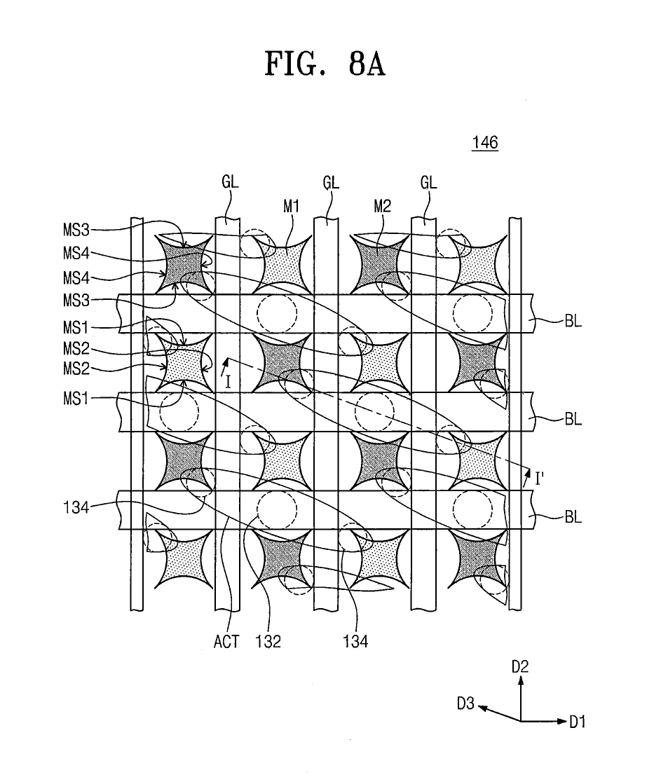

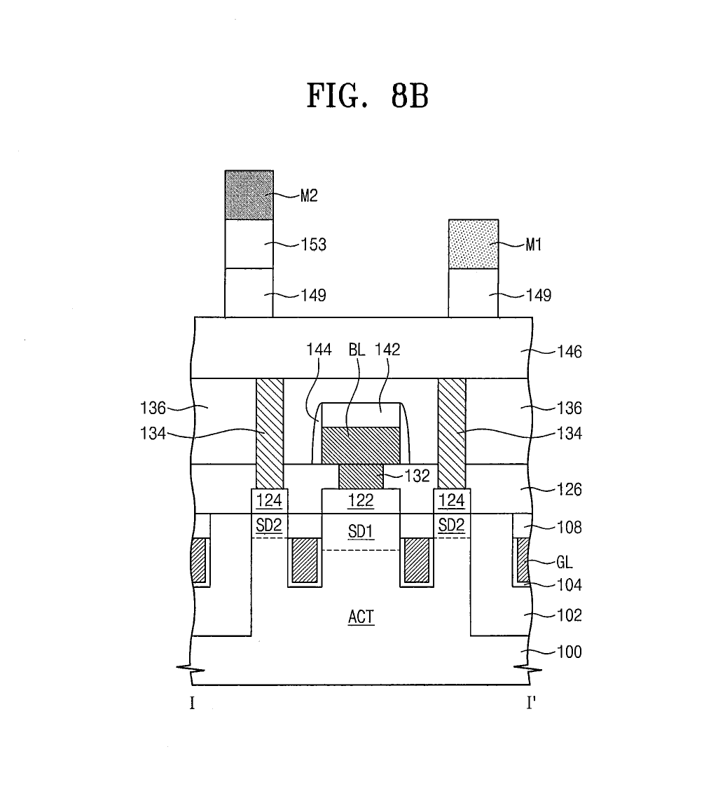

Referring to FIGS. 8A and 8B, the upper and lower mask layers 152 and 148 may be sequentially etched using the second and first mask patterns M2 and M1, respectively, as an etch mask to form upper mask patterns 153 and lower mask patterns 149. The upper mask patterns 153 may be positioned at substantially the same level as that of the first mask patterns M1. The lower mask patterns 149 may be formed below the first and second mask patterns M1 and M2, respectively. Accordingly, the lower mask patterns 149 may be arranged in the first direction D1 and the second direction D2 to form a square arrangement, when viewed in a plan view. The etching process may be performed to expose the top surface of the first mold layer 146.

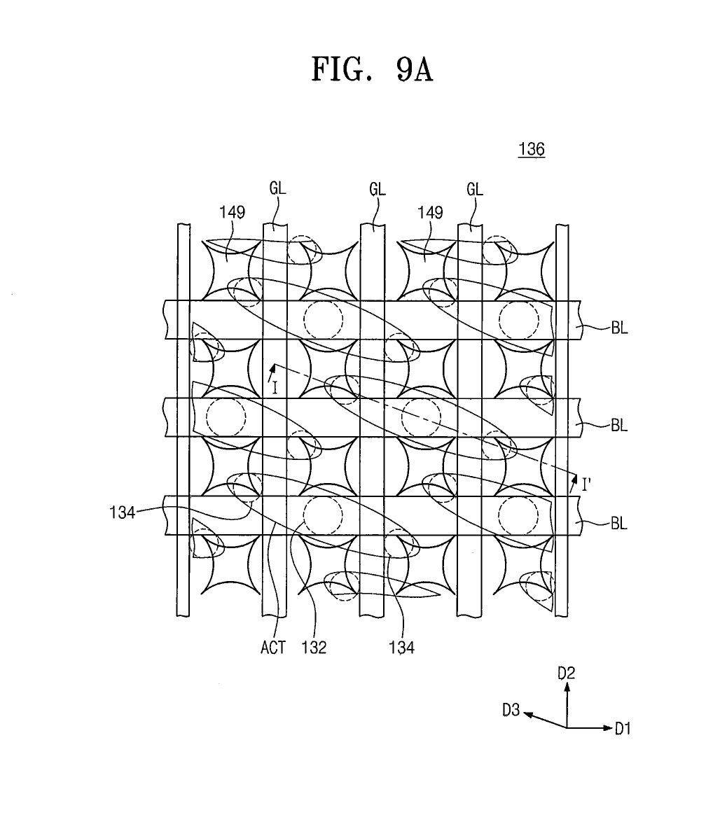

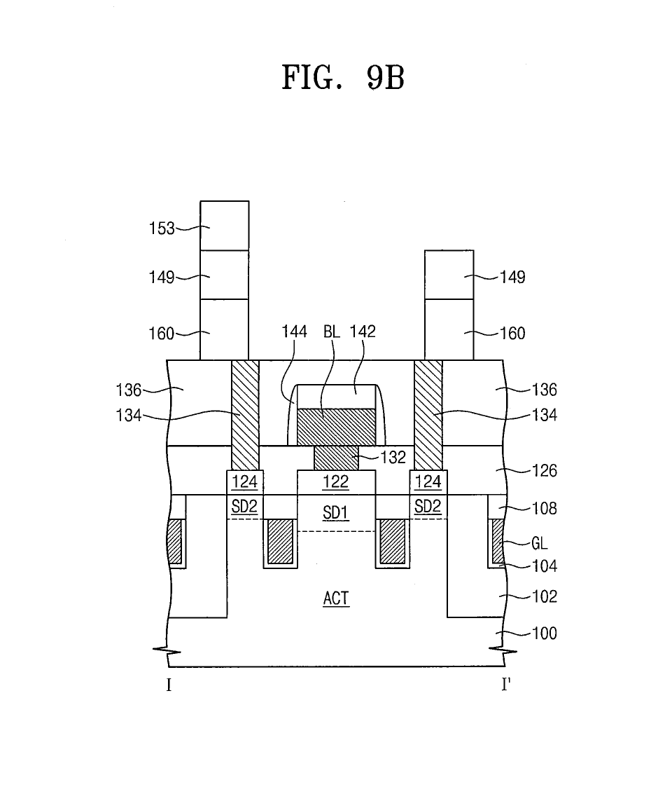

Referring to FIGS. 9A and 9B, the first mold layer 146 may be etched using the upper and lower mask patterns 153 and 149 as an etch mask to form mold patterns 160. In example embodiments, the etching process may be performed to remove the first and second mask patterns M1 and M2. However, in other example embodiments, unlike the example illustrated, the first and second mask patterns M1 and M2 may partially remain on the upper and lower mask patterns 153 and 149, even after the etching process. The etching process may be performed to expose the top surface of the second interlayer insulating layer 136.

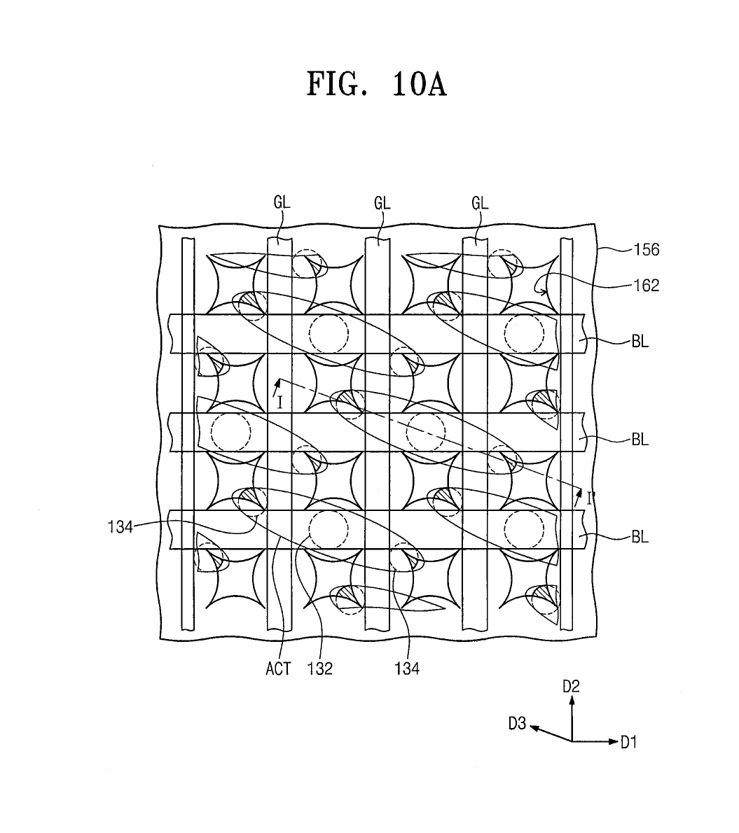

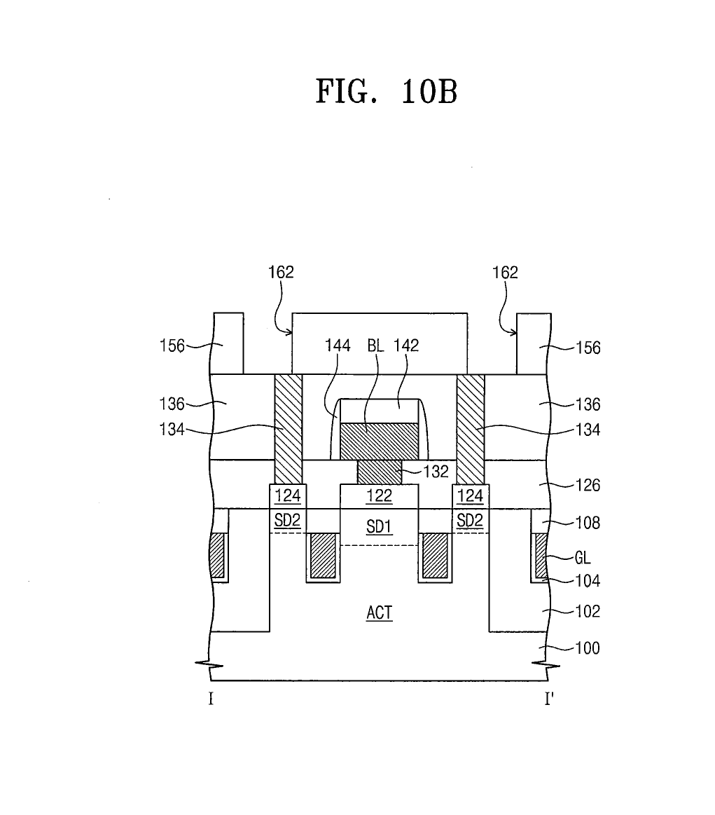

Referring to FIGS. 10A and 10B, a second mold layer 156 may be formed on the second interlayer insulating layer 136 to cover the mold patterns 160. The second mold layer 156 may be formed of a material having an etch selectivity with respect to the mold patterns 160 and the second interlayer insulating layer 136. For example, in the case where the second mold layer 156 is formed of a silicon oxide layer, the second interlayer insulating layer 136 may include a silicon nitride layer provided at the uppermost level thereof. A planarization process may be performed on an upper portion of the second mold layer 156 to expose top surfaces of the mold patterns 160. Thereafter, the mold patterns 160 may be removed to form openings 162 in the second mold layer 156. The removal of the mold patterns 160 may be performed using, for example, a wet etching process. The openings 162 may be formed to expose top surfaces of the buried contacts 134, respectively.

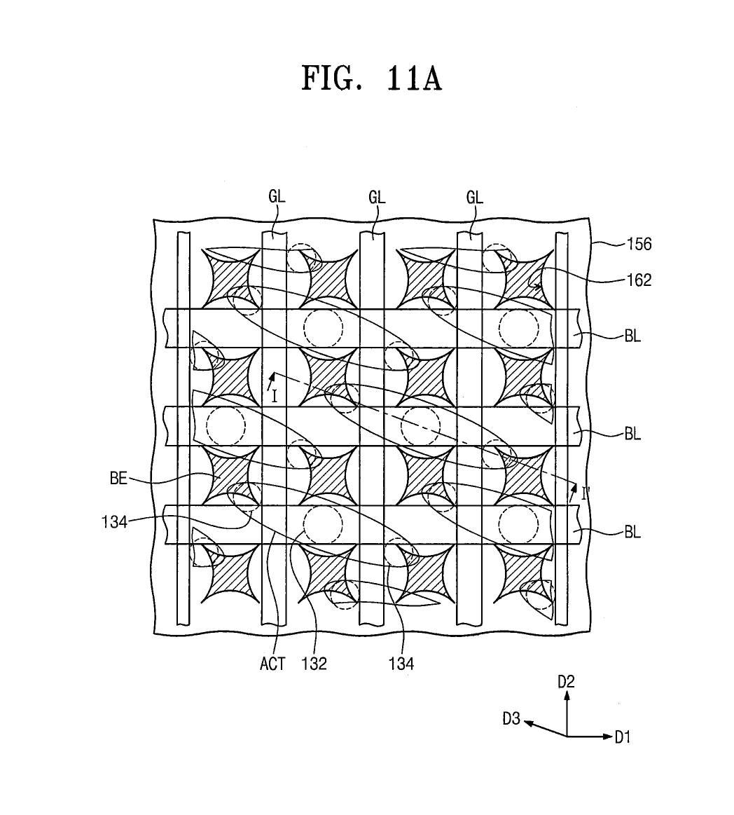

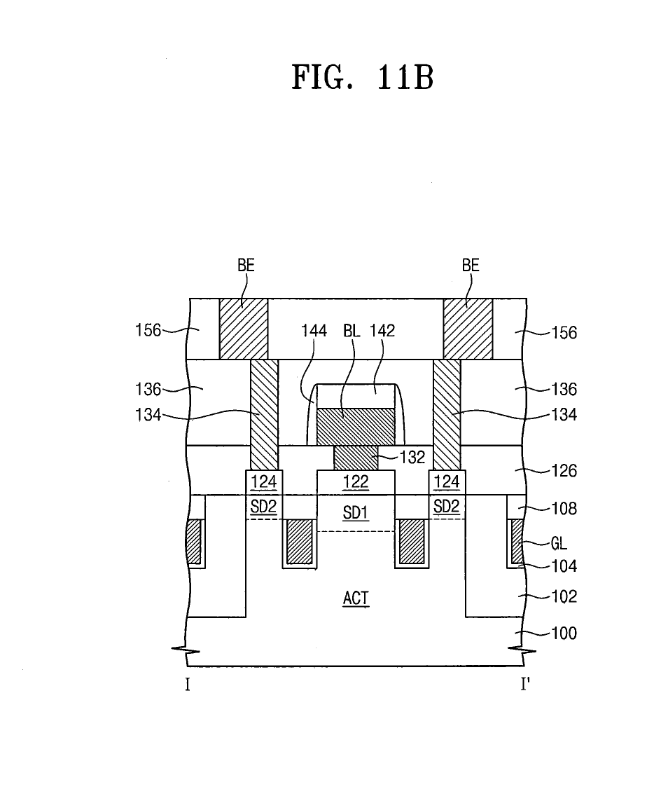

Referring to FIGS. 11A and 11B, bottom electrodes BE may be formed in the openings 162, respectively. The formation of the bottom electrodes BE may include forming a conductive layer on the second mold layer 156 to fill the openings 162, and then, planarizing the conductive layer to expose a top surface of the second mold layer 156. The bottom electrodes BE may be connected to the buried contacts 134, respectively.

Referring back to FIGS. 1A and 1B, the second mold layer 156 may be removed. The removal of the second mold layer 156 may include etching the second mold layer 156 using an etch recipe having an etch selectivity with respect to the second interlayer insulating layer 136. Next, a dielectric layer 150 and a top electrode TE may be sequentially formed on the second interlayer insulating layer 136 to cover the bottom electrodes BE. The dielectric layer 150 and the top electrode TE may be formed using a layer-forming technique (e.g., chemical vapor deposition (CVD) or atomic layer deposition (ALD)) with a good step coverage property or a physical vapor deposition (PVD).

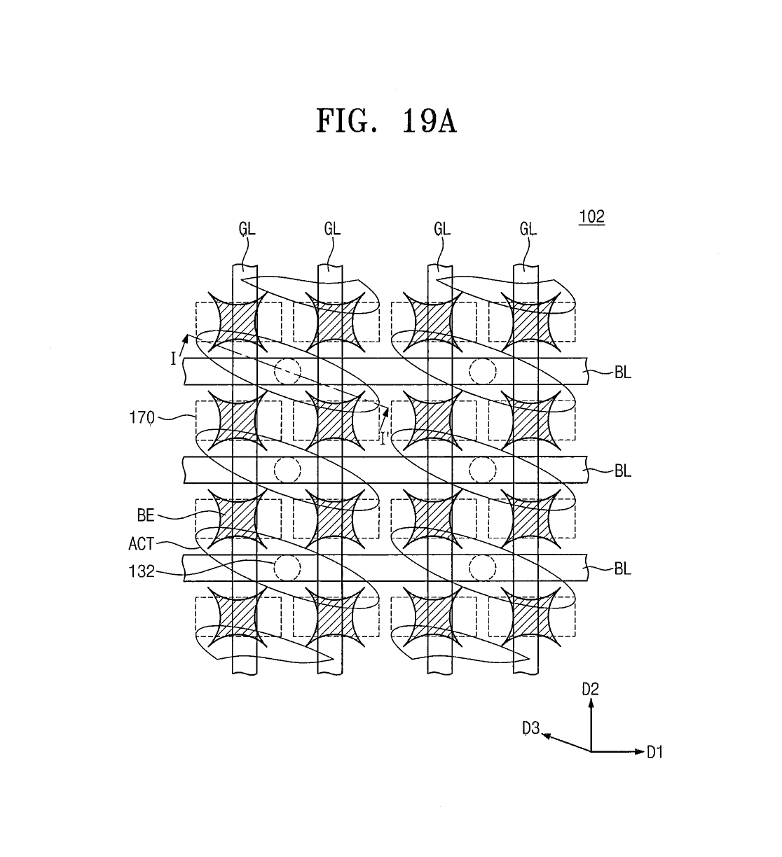

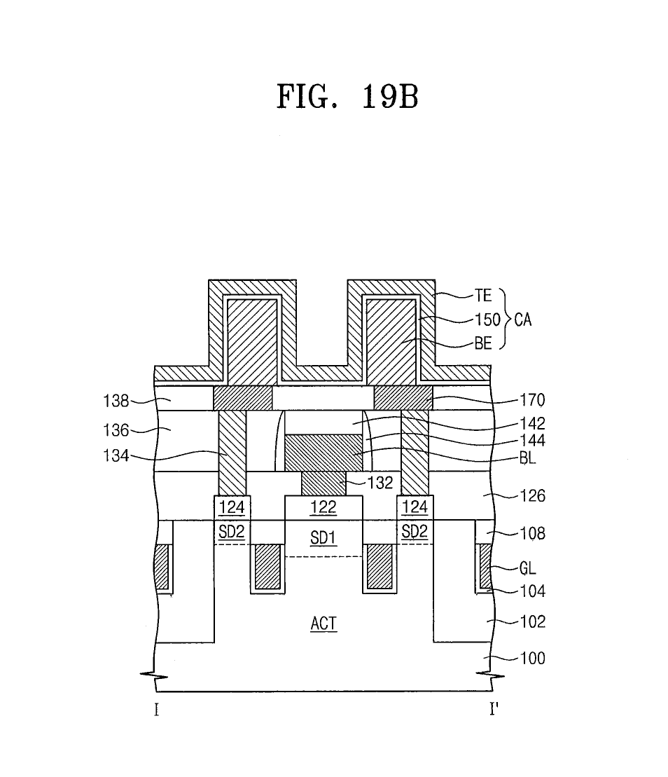

FIG. 19A is a plan view illustrating a semiconductor device according to further embodiments of the inventive concept, and FIG. 19B is a sectional view taken along line of FIG. 19A. For concise description, an element previously described with reference to FIGS. 1A and 1B may be identified by a similar or identical reference number without repeating an overlapping description thereof.

Referring to FIGS. 19A and 19B, a device isolation layer 102 may be provided on a substrate 100 to define active regions ACT. When viewed in a plan view, each of the active regions ACT may be shaped like a bar, whose longitudinal axis is parallel to a third direction D3 or is at an angle to first and second directions D1 and D2 crossing each other. According to the embodiment described with reference to FIGS. 1A and 1B, the active regions ACT may be arranged in a zigzag manner in the second direction D2, but according to the present embodiments, the active regions ACT may be arranged in a columnar arrangement manner in the second direction D2, as shown in FIG. 19A.

According to the present embodiments, capacitors CA may be electrically connected to respective second doped regions SD2, which are provided in the active regions ACT, through conductive pads 170 and buried contacts 134. The capacitors CA may include bottom electrodes BE, which are connected to the conductive pads 170, respectively.

In the present embodiment, a semiconductor device, except for the afore-described differences, may be configured to have substantially the same features as those of FIGS. 1A and 1B. Further, the bottom electrodes BE may be configured to have substantially the same arrangement and shapes as those described with reference to FIGS. 2, 3, 4A through 4G, and 5A through 5K.

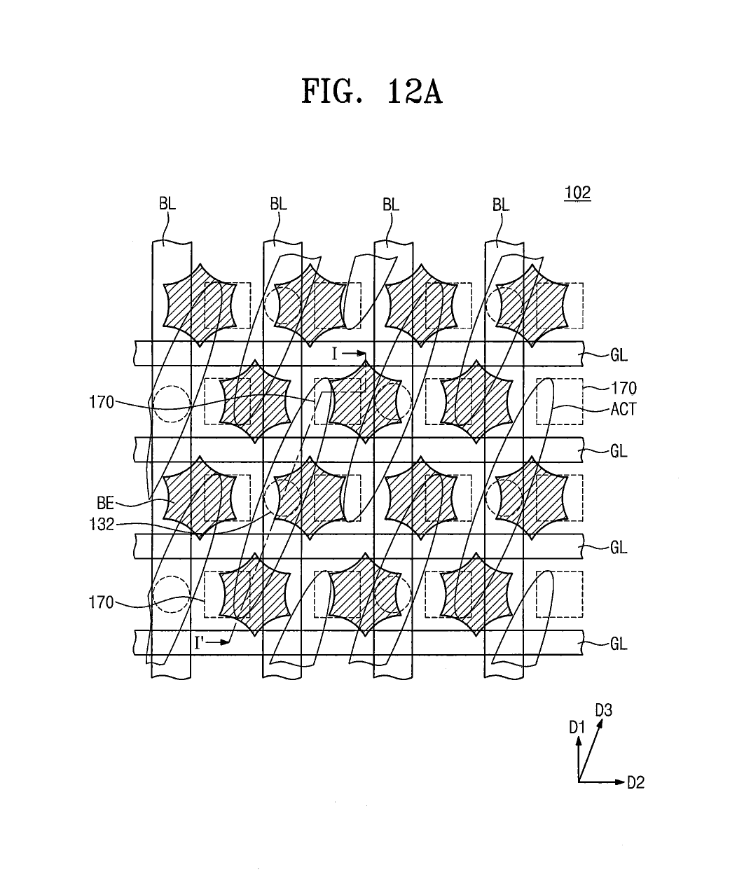

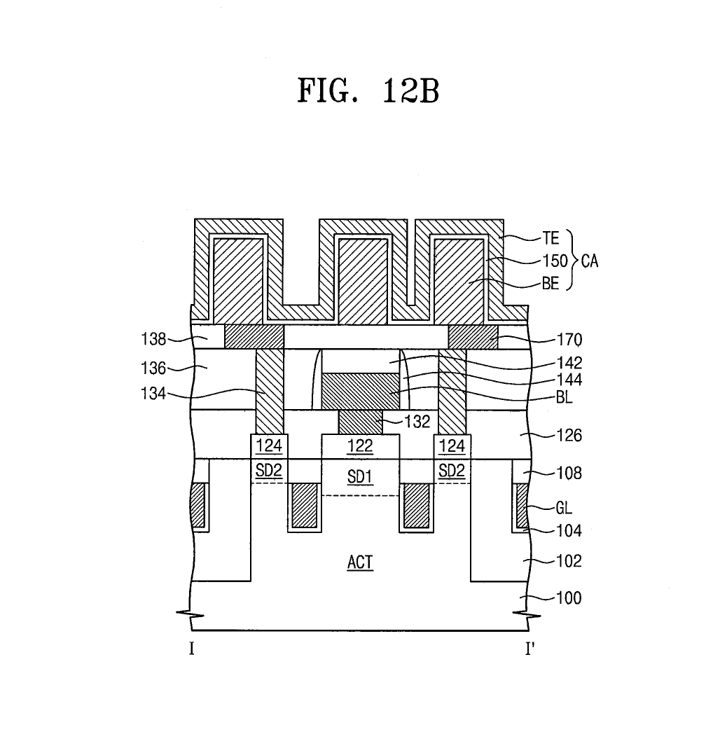

FIG. 12A is a plan view illustrating a semiconductor device according to a further embodiment of the inventive concept, and FIG. 12B is a sectional view taken along line I-I′ of FIG. 12A. For concise description, an element previously described with reference to FIGS. 1A and 1B may be identified by a similar or identical reference number without repeating an overlapping description thereof.

Referring to FIGS. 12A and 12B, a device isolation layer 102 may be provided on a substrate 100 to define active regions ACT. When viewed in a plan view, each of the active regions ACT may be shaped like a bar, whose longitudinal axis is parallel to a third direction D3 or is at an angle to first and second directions D1 and D2 crossing each other.

Gate lines GL may be provided in the substrate 100 to cross the active regions ACT. The gate lines GL may extend parallel to the second direction D2 and may be arranged in the first direction D1. The gate lines GL may be buried in the substrate 100. Gate insulating patterns 104 may be interposed between the gate lines GL and the active regions ACT and between the gate lines GL and the device isolation layer 102. First capping patterns 108 may be provided on top surfaces of the gate lines GL, respectively.

A first doped region SD1 and second doped regions SD2 may be provided in each of the active regions ACT, and here, the second doped regions SD2 may be spaced apart from each other by the first doped region SD1. The first doped region SD1 may be provided in a portion of the active region ACT that is positioned between an adjacent pair of the gate lines GL. The second doped regions SD2 may be provided in end portions of the active region ACT that are spaced apart from each other by the pair of gate lines GL. In other words, the second doped regions SD2 may be spaced apart from each other with the pair of gate lines GL interposed therebetween. The first doped region SD1 may have a depth greater than that of the second doped regions SD2, when measured from the top surface of the substrate 100. The first doped region SD1 may be doped to have the same conductivity type as the second doped region SD2.

A first pad 122 and second pads 124 may be provided on the substrate 100. The first pad 122 may be connected to the first doped region SD1, and the second pads 124 may be connected to the second doped regions SD2, respectively. A first interlayer insulating layer 126 may be provided on the substrate 100 to cover the first pad 122 and the second pads 124.

Bit lines BL may be provided on the first interlayer insulating layer 126. The bit lines BL may extend parallel to the first direction D1 and may be spaced apart from each other in the second direction D2. Each of the bit lines BL may be electrically connected to the first doped region SD1 through the first pad 122 and a bit line contact 132. The bit line contact 132 may penetrate the first interlayer insulation layer 126 and be connected to the first pad 122. Second capping patterns 142 may be provided on top surfaces of the bit lines BL, respectively, and bit line spacers 144 may be provided on both side surfaces of the bit lines BL, respectively.

A second interlayer insulating layer 136 may be provided on the first interlayer insulating layer 126 to cover the bit lines BL, the second capping patterns 142, and the bit line spacers 144. In addition, buried contacts 134 may be provided on the substrate 100 to penetrate the first and second interlayer insulating layers 126 and 136 and be in contact with the second pads 124, respectively.

A third interlayer insulating layer 138 may be provided on the second interlayer insulating layer 136. The third interlayer insulating layer 138 may include, for example, a silicon nitride layer and/or a silicon oxynitride layer. Conductive pads 170 may be provided in the third interlayer insulating layer 138. For example, the conductive pads 170 may be connected to the buried contacts 134, respectively, through the third interlayer insulating layer 138. The conductive pads 170 may include a conductive material (e.g., doped silicon or a metal).

Capacitors CA may be provided on the third interlayer insulating layer 138 and may be electrically connected to the second doped regions SD2, respectively, through the conductive pads 170 and the buried contacts 134. Each of the capacitors CA may include a bottom electrode BE, which is provided on the third interlayer insulating layer 138 and is connected to a corresponding one of the conductive pads 170. The bottom electrodes BE may be electrically connected to the second doped regions SD2, respectively, through the conductive pads 170 and the buried contacts 134. Each of the bottom electrodes BE may have a solid pillar shape, as shown in FIG. 1B. However, in other embodiments, each of the bottom electrodes BE may be shaped like a bottom-closed hollow cylinder. When viewed in a plan view, the bottom electrodes BE may be two-dimensionally arranged on the substrate 100. The arrangement and shape of the bottom electrodes BE according to the present embodiment will be described in more detail below.

The capacitor CA may further include a top electrode TE, which is provided on the second interlayer insulating layer 136 to cover the bottom electrodes BE, and a dielectric layer 150 interposed between the bottom electrodes BE and the top electrode TE.

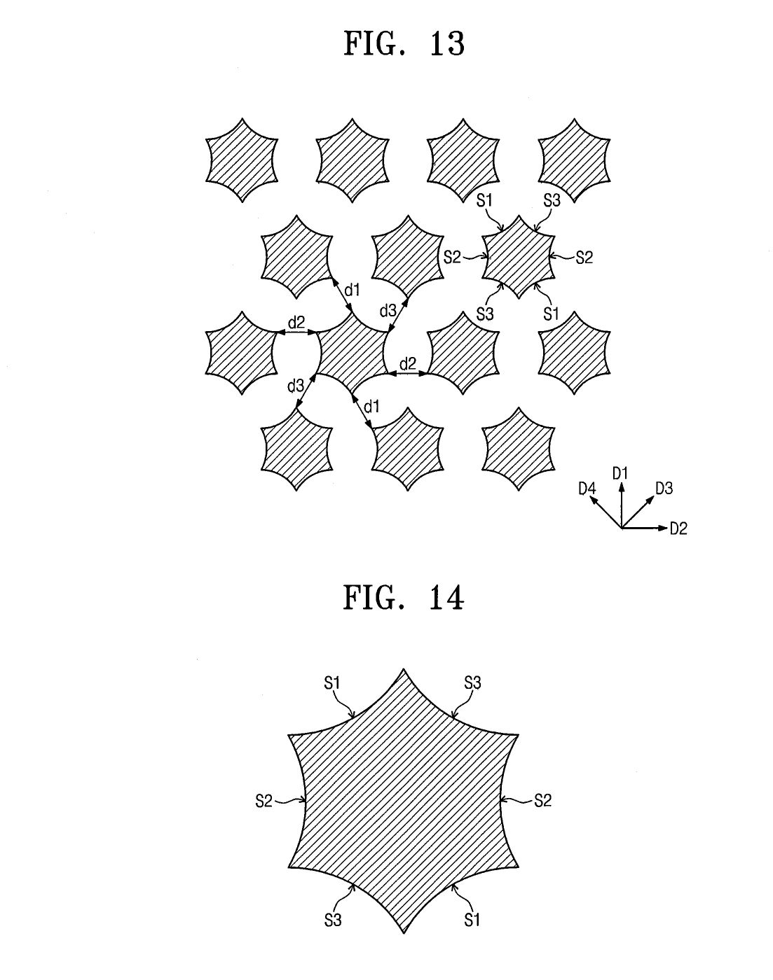

FIG. 13 is a plan view illustrating a planar arrangement of bottom electrodes provided in the semiconductor device according to the further embodiment of the inventive concept, and FIG. 14 is a plan view illustrating a planar shape of each bottom electrode provided in the semiconductor device according to the further embodiment of the inventive concept.

Referring to FIG. 13, the bottom electrodes BE may be arranged in the first direction D1 and the second direction D2 to form a honeycomb arrangement, when viewed in a plan view.

Each of the bottom electrodes BE may include first side surfaces S1, which are provided to face each other, second side surfaces S2, which are provided between the first side surfaces S1 to face each other, and third side surfaces S3, which are provided between the first side surfaces S1 to face each other. One end of each of the second side surfaces S2 may be connected to one end of a corresponding one of the first side surfaces S1, and the other end of each of the second side surfaces S2 may be connected to one end of a corresponding one of the third side surfaces S3. The other end of each of the first side surfaces S1 may be connected to the other end of a corresponding one of the third side surfaces S3.

The first side surfaces S1 may face each other in a fourth direction D4 crossing all of the first, second, and third directions D1, D2, and D3. The second side surfaces S2 may face each other in the second direction D2, and the third side surfaces S3 may face each other in the third direction D3.

Each of the first side surfaces S1 may be spaced apart from a side surface of another bottom electrode BE adjacent thereto by a first distance d1. Each of the second side surfaces S2 may be spaced apart from a side surface of another bottom electrode BE adjacent thereto by a second distance d2. Further, each of the third side surfaces S3 may be spaced apart from a side surface of another bottom electrode BE adjacent thereto by a third distance d3. Here, the first distance d1 may be the shortest distance between the first side surface S1 and a side surface of one of the bottom electrodes BE, which is positioned most adjacent thereto in the fourth direction D4, and the second distance d2 may be the shortest distance between the second side surface S2 and a side surface of one of the bottom electrodes BE, which is positioned most adjacent thereto in the second direction D2. Further, the third distance d3 may be the shortest distance between the third side surface S3 and a side surface of one of the bottom electrodes BE, which is positioned most adjacent thereto in the third direction D3. In example embodiments, the first, second, and third distances d1, d2, and d3 may be substantially the same. The first, second, and third distances d1, d2, and d3 may be a minimum separation distance required for electrically separating the bottom electrodes BE from each other.

A pair of the bottom electrodes BE, which are positioned adjacent to the first side surfaces S1, respectively, may be disposed spaced apart from each other in the fourth direction D4, and another pair of the bottom electrodes BE, which are positioned adjacent to the second side surfaces S2, respectively, may be disposed spaced apart from each other in the second direction D2. Further, a pair of the bottom electrodes BE, which are positioned adjacent to the third side surfaces S3, respectively, may be disposed spaced apart from each other in the third direction D3. The first side surfaces S1 may be disposed spaced apart from respective ones of the bottom electrodes BE paired and arranged in the fourth direction D4 by the first distance d1. The second side surfaces S2 may be disposed spaced apart from respective ones of the bottom electrodes BE paired and arranged in the second direction D2 by the second distance d2. The third side surfaces S3 may be disposed spaced apart from respective ones of the bottom electrodes BE paired and arranged in the third direction D3 by the third distance d3.

Referring to FIG. 14, each of the first, second, and third side surfaces S1, S2, and S3 may have a concave shape. In example embodiments, when viewed in a plan view, the first, second, and third side surfaces S1, S2, and S3 may be concavely curved in a direction toward a center of the bottom electrode BE. The first side surfaces S1 may have shapes substantially symmetrical to each other, and the second side surfaces S2 may also have shapes substantially symmetrical to each other. In addition, the third side surfaces S3 may have shapes substantially symmetrical to each other.

According to example embodiments of the inventive concept, the bottom electrodes BE may be disposed spaced apart from each other by at least a minimum separation distance required for electrically separating the bottom electrodes BE from each other, and side surfaces of each bottom electrode BE may have a concave shape. Accordingly, it is possible to form each of the bottom electrodes BE having an increased surface area in a limited planar area, without concern for breakage of electric isolation.

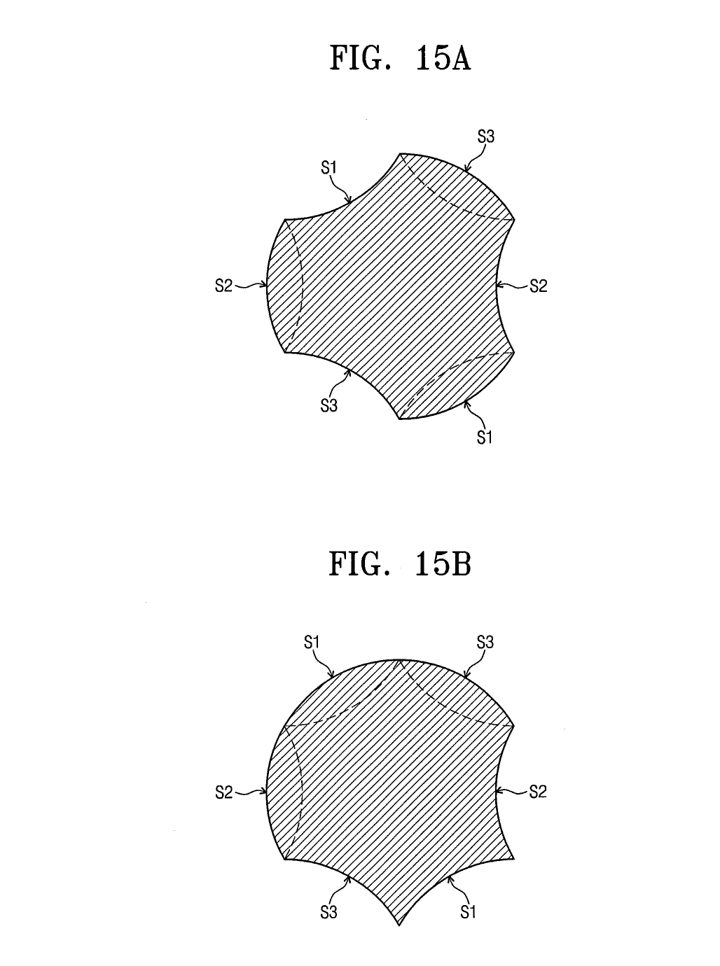

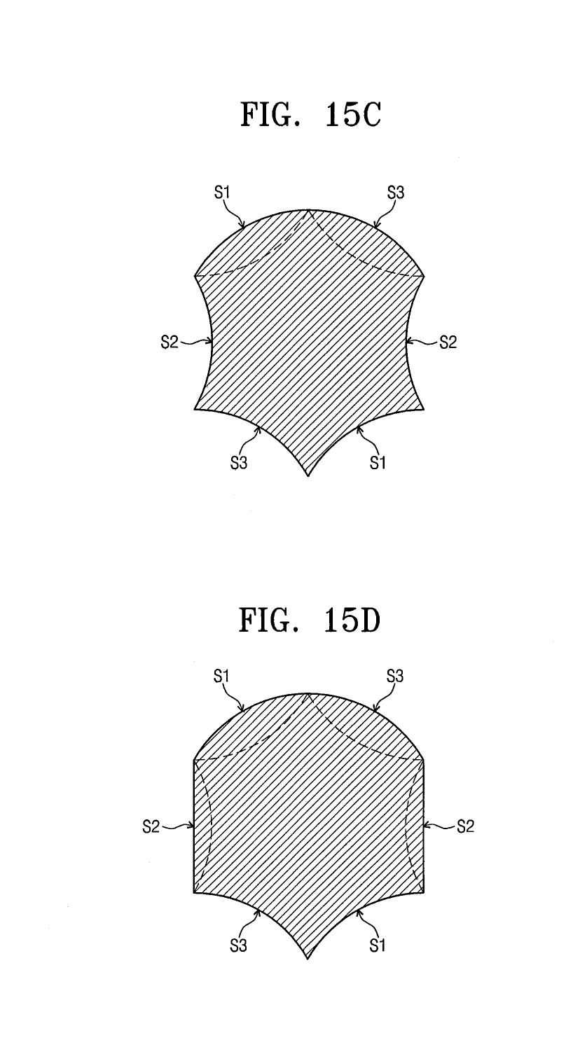

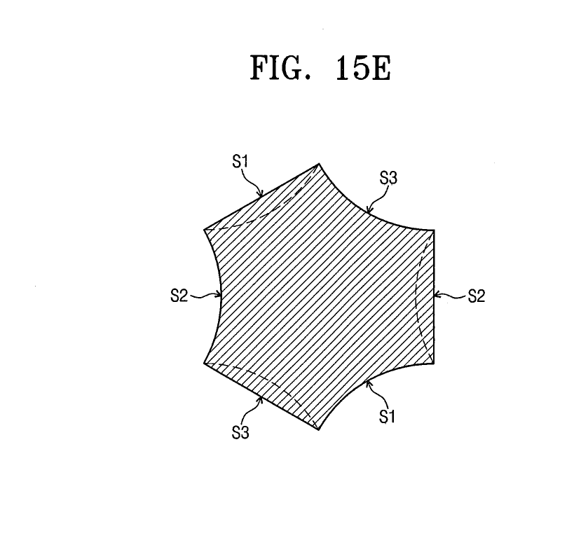

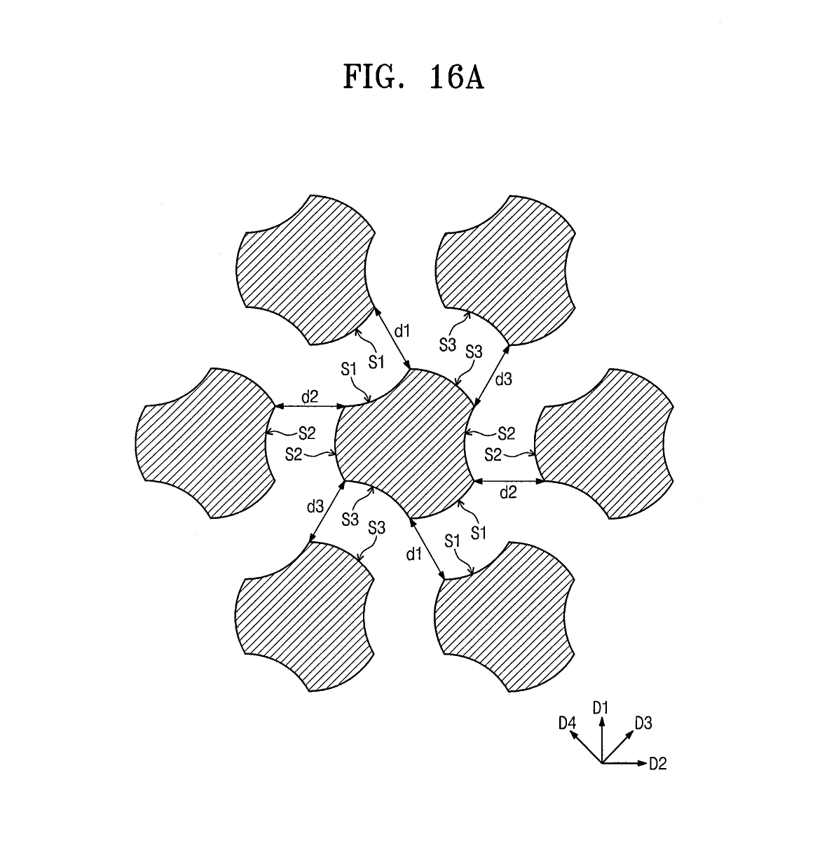

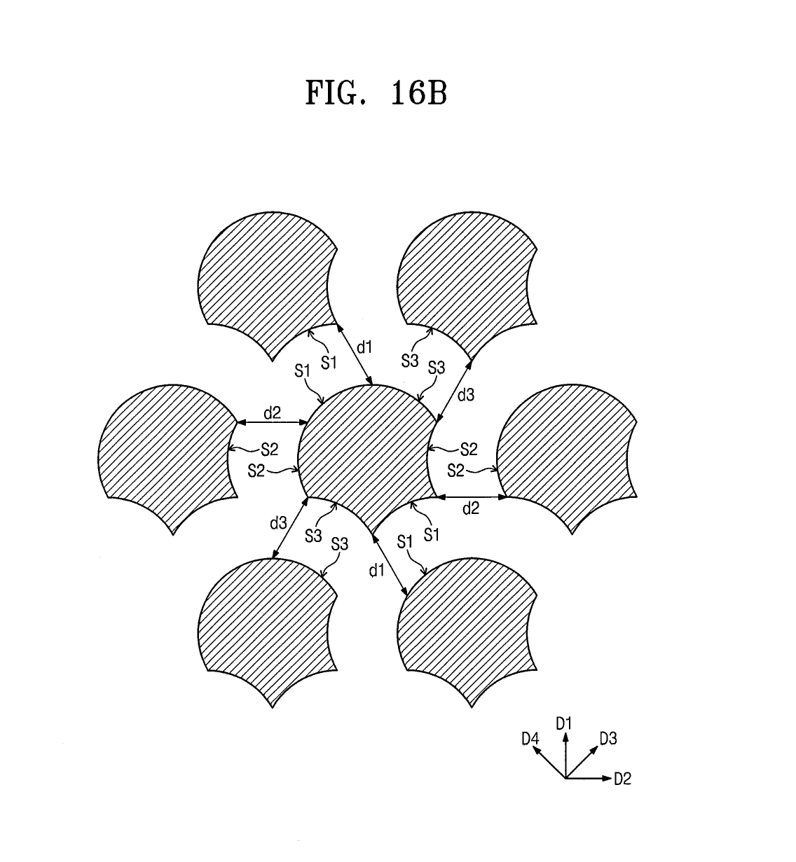

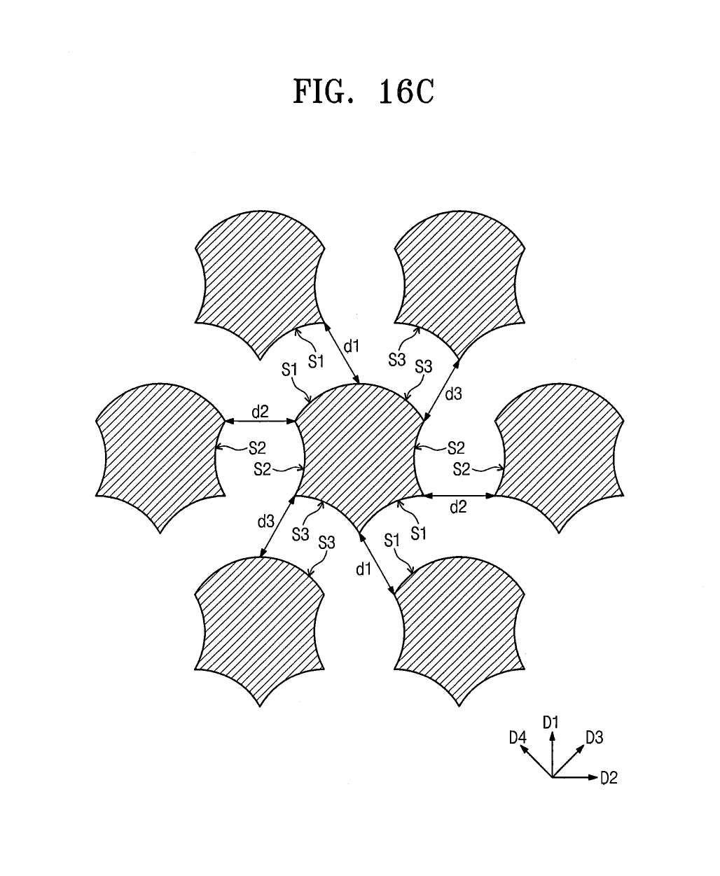

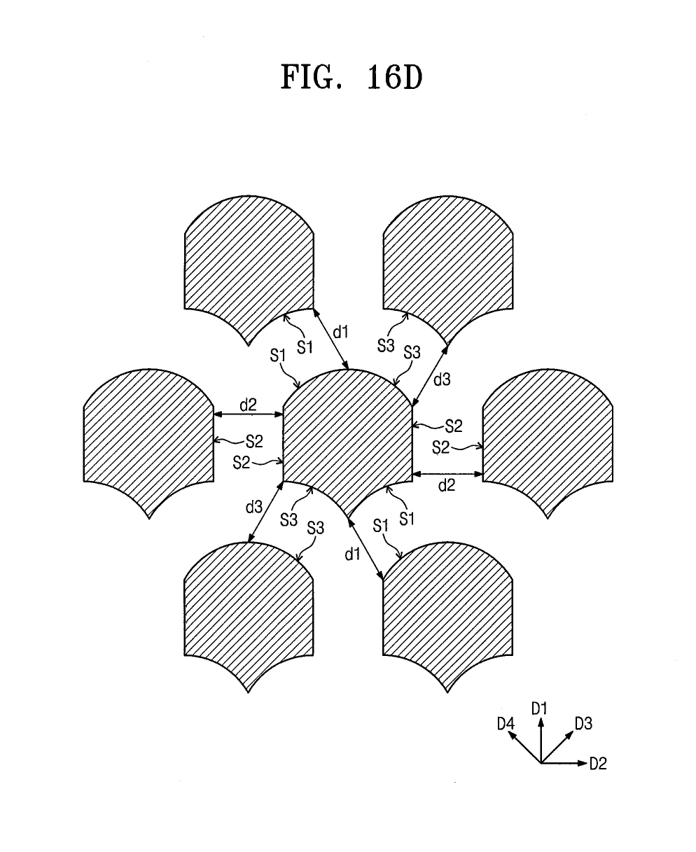

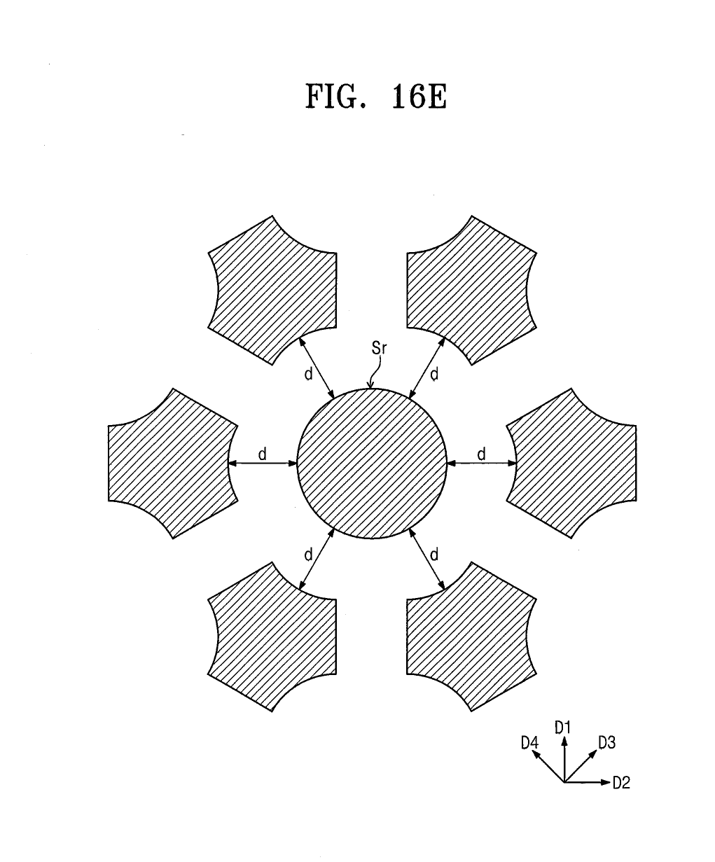

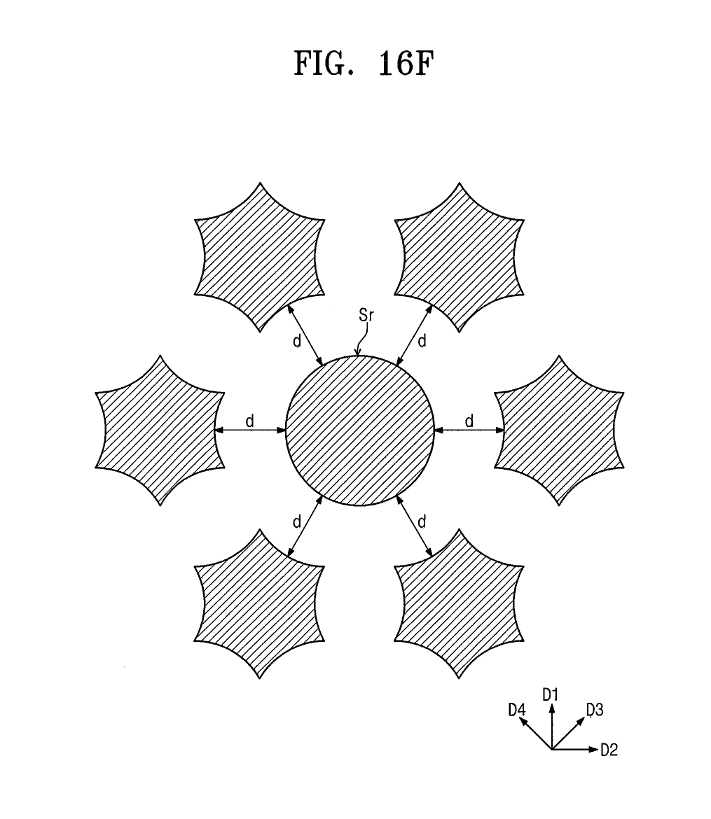

FIGS. 15A through 15E are plan views illustrating modified planar shapes of each bottom electrode provided in the semiconductor device according to the further embodiment of the inventive concept. FIGS. 16A through 16F are plan views, each of which illustrates a modified planar arrangement of the bottom electrodes provided in the semiconductor device according to the further embodiment of the inventive concept.

Referring to FIG. 15A, when viewed in a plan view, the first side surfaces S1 may have shapes substantially asymmetrical to each other, and the second side surfaces S2 may also have shapes substantially asymmetrical to each other. The third side surfaces S3 may also have shapes substantially asymmetrical to each other. For example, one of the first side surfaces S1 may have a convex shape, and the other of the first side surfaces S1 may have a concave shape. One of the second side surfaces S2 may have a convex shape, and the other of the second side surfaces S2 may have a concave shape. Further, one of the third side surfaces S3 may have a convex shape, and the other of the third side surfaces S3 may have a concave shape. Both ends of a convexly-curved one of the first side surfaces S1 may be connected to one end of a concavely-curved one of the second side surfaces S2 and one end of a concavely-curved one of the third side surfaces S3, respectively. Both ends of a concavely-curved one of the first side surfaces S1 may be connected to one end of a convexly-curved one of the second side surfaces S2 and one end of a convexly-curved one of the third side surfaces S3, respectively.

In the case where each of the bottom electrodes BE has the shape of FIG. 15A, the bottom electrodes BE may be disposed to form an arrangement shown in FIG. 16A. As shown in FIG. 16A, a pair of the bottom electrodes BE, which are positioned adjacent to the first side surfaces S1, respectively, may be disposed spaced apart from each other in the fourth direction D4, and another pair of the bottom electrodes BE, which are positioned adjacent to the second side surfaces S2, respectively, may be disposed spaced apart from each other in the second direction D2. A pair of the bottom electrodes BE, which are positioned adjacent to the third side surfaces S3, respectively, may be disposed spaced apart from each other in the third direction D3. A convexly-curved one of the first side surfaces S1 may be disposed to face a concavely-curved one of the first side surfaces S1 of a neighboring one of the bottom electrodes BE, while a concavely-curved one of the first side surfaces S1 may be disposed to face a convexly-curved one of the first side surfaces S1 of a neighboring one of the bottom electrodes BE. Further, a convexly-curved one of the second side surfaces S2 may be disposed to face a concavely-curved one of the second side surfaces S2 of a neighboring one of the bottom electrodes BE, while a concavely-curved one of the second side surfaces S2 may be disposed to face a convexly-curved one of the second side surfaces S2 of a neighboring one of the bottom electrodes BE. Further, a convexly-curved one of the third side surfaces S3 may be disposed to face a concavely-curved one of the third side surfaces S3 of a neighboring one of the bottom electrodes BE, while a concavely-curved one of the third side surfaces S3 may be disposed to face a convexly-curved one of the third side surfaces S3 of a neighboring one of the bottom electrodes BE. In other words, a convex side surface of one of a pair of the bottom electrodes BE, which are positioned adjacent to each other, may be disposed to face a concave side surface of the other of the pair of the bottom electrodes BE. Accordingly, the first side surfaces S1 may be disposed equidistant apart from respective ones of the bottom electrodes BE paired and arranged in the fourth direction D4 by the first distance d1, and the second side surfaces S2 may be disposed equidistant apart from respective ones of the bottom electrodes BE paired and arranged in the second direction D2 by the second distance d2. Further, the third side surfaces S3 may be disposed equidistant apart from respective ones of the bottom electrodes BE paired and arranged in the third direction D3 by the third distance d3.

Referring to FIG. 15B, when viewed in a plan view, the first side surfaces S1 may have shapes substantially asymmetrical to each other, and the second side surfaces S2 may also have shapes substantially asymmetrical to each other. The third side surfaces S3 may also have shapes substantially asymmetrical to each other. For example, one of the first side surfaces S1 may have a convex shape, and the other of the first side surfaces S1 may have a concave shape. One of the second side surfaces S2 may have a convex shape, and the other of the second side surfaces S2 may have a concave shape. Further, one of the third side surfaces S3 may have a convex shape, and the other of the third side surfaces S3 may have a concave shape. Unlike that of FIG. 15A, both ends of a concavely-curved one of the first side surfaces S1 may be connected to one end of a concavely-curved one of the second side surfaces S2 and one end of a concavely-curved one of the third side surfaces S3, respectively. Further, both ends of a convexly-curved one of the first side surfaces S1 may be connected to one end of a convexly-curved one of the second side surfaces S2 and one end of a convexly-curved one of the third side surfaces S3, respectively.

In the case where each of the bottom electrodes BE has the shape of FIG. 15B, the bottom electrodes BE may be disposed to form an arrangement shown in FIG. 16B. Referring to FIG. 16B, a pair of the bottom electrodes BE, which are positioned adjacent to the first side surfaces S1, respectively, may be disposed spaced apart from each other in the fourth direction D4, and another pair of the bottom electrodes BE, which are positioned adjacent to the second side surfaces S2, respectively, may be disposed spaced apart from each other in the second direction D2. A pair of the bottom electrodes BE, which are positioned adjacent to the third side surfaces S3, respectively, may be disposed spaced apart from each other in the third direction D3. As described with reference to FIG. 16A, one of a pair of the bottom electrodes BE, which are positioned adjacent to each other, may be disposed in such a way that a convex side surface thereof faces a concave side surface of the other of the pair of the bottom electrodes BE. Accordingly, the first side surfaces S1 may be disposed equidistant apart from respective ones of the bottom electrodes BE paired and arranged in the fourth direction D4 by the first distance d1, and the second side surfaces S2 may be disposed equidistant apart from respective ones of the bottom electrodes BE paired and arranged in the second direction D2 by the second distance d2. Further, the third side surfaces S3 may be disposed equidistant apart from respective ones of the bottom electrodes BE paired and arranged in the third direction D3 by the third distance d3.

Referring to FIG. 15C, when viewed in a plan view, the first side surfaces S1 may have shapes substantially asymmetrical to each other, and the third side surfaces S3 may also have shapes substantially asymmetrical to each other. The second side surfaces S2 may have shapes substantially symmetrical to each other. For example, one of the first side surfaces S1 may have a convex shape, and the other of the first side surfaces S1 may have a concave shape. One of the third side surfaces S3 may have a convex shape, and the other of the third side surfaces S3 may have a concave shape. Each of the second side surfaces S2 may have a concave shape. Both ends of a concavely-curved one of the first side surfaces S1 may be connected to one end of one of the second side surfaces S2 and one end of a concavely-curved one of the third side surfaces S3, respectively. Further, both ends of a convexly-curved one of the first side surfaces S1 may be connected to one end of the other of the second side surfaces S2 and one end of a convexly-curved one of the third side surfaces S3, respectively.

In the case where each of the bottom electrodes BE has the shape of FIG. 15C, the bottom electrodes BE may be disposed to form an arrangement shown in FIG. 16C. Referring to FIG. 16C, a pair of the bottom electrodes BE, which are positioned adjacent to the first side surfaces S1, respectively, may be disposed spaced apart from each other in the fourth direction D4, and another pair of the bottom electrodes BE, which are positioned adjacent to the second side surfaces S2, respectively, may be disposed spaced apart from each other in the second direction D2. A pair of the bottom electrodes BE, which are positioned adjacent to the third side surfaces S3, respectively, may be disposed spaced apart from each other in the third direction D3. The second side surfaces S2 may be disposed to face respective second side surfaces S2 of the pair of the bottom electrodes BE paired and arranged in the second direction D2. Accordingly, the second side surfaces S2 may be disposed spaced apart from respective ones of the bottom electrodes BE paired and arranged in the second direction D2 by the second distance d2. Further, as described with reference to FIG. 16A, one of a pair of the bottom electrodes BE, which are positioned adjacent to each other, may be disposed in such a way that a convex side surface thereof faces a concave side surface of the other of the pair of the bottom electrodes BE. Accordingly, the first side surfaces S1 may be disposed equidistant apart from respective ones of the bottom electrodes BE paired and arranged in the fourth direction D4 by the first distance d1, and the third side surfaces S3 may be disposed equidistant apart from respective ones of the bottom electrodes BE paired and arranged in the third direction D3 by the third distance d3.

Referring to FIG. 15D, when viewed in a plan view, the first side surfaces S1 may have shapes substantially asymmetrical to each other, and the third side surfaces S3 may also have shapes substantially asymmetrical to each other. The second side surfaces S2 may have shapes substantially symmetrical to each other. For example, one of the first side surfaces S1 may have a convex shape, and the other of the first side surfaces S1 may have a concave shape. One of the third side surfaces S3 may have a convex shape, and the other of the third side surfaces S3 may have a concave shape. Unlike that of FIG. 15C, each of the second side surfaces S2 may have a linear shape. Both ends of a concavely-curved one of the first side surfaces S1 may be connected to one end of one of the second side surfaces S2 and one end of a concavely-curved one of the third side surfaces S3, respectively. Further, both ends of a convexly-curved one of the first side surfaces S1 may be connected to one end of the other of the second side surfaces S2 and one end of a convexly-curved one of the third side surfaces S3, respectively.

In the case where each of the bottom electrodes BE has the shape of FIG. 15D, the bottom electrodes BE may be disposed to form an arrangement shown in FIG. 16D. Referring to FIG. 16D, a pair of the bottom electrodes BE, which are positioned adjacent to the first side surfaces S1, respectively, may be disposed spaced apart from each other in the fourth direction D4, and another pair of the bottom electrodes BE, which are positioned adjacent to the second side surfaces S2, respectively, may be disposed spaced apart from each other in the second direction D2. Other pair of the bottom electrodes BE, which are positioned adjacent to the third side surfaces S3, respectively, may be disposed spaced apart from each other in the third direction D3. The second side surfaces S2 may be disposed to face respective second side surfaces S2 of the pair of the bottom electrodes BE paired and arranged in the second direction D2. Accordingly, the second side surfaces S2 may be disposed equidistant apart from respective ones of the bottom electrodes BE paired and arranged in the second direction D2 by the second distance d2. Further, as described with reference to FIG. 16A, one of a pair of the bottom electrodes BE, which are positioned adjacent to each other, may be disposed in such a way that a convex side surface thereof faces a concave side surface of the other of the pair of the bottom electrodes BE. Accordingly, the first side surfaces S1 may be disposed equidistant apart from respective ones of the bottom electrodes BE paired and arranged in the fourth direction D4 by the first distance d1, and the third side surfaces S3 may be disposed equidistant apart from respective ones of the bottom electrodes BE paired and arranged in the third direction D3 by the third distance d3.

Referring to FIG. 15E, when viewed in a plan view, the first side surfaces S1 may have shapes substantially asymmetrical to each other, and the second side surfaces S2 may also have shapes substantially asymmetrical to each other. The third side surfaces S3 may also have shapes substantially asymmetrical to each other. For example, one of the first side surfaces S1 may have a concave shape, and the other of the first side surfaces S1 may have a linear shape. One of the second side surfaces S2 may have a concave shape, and the other of the second side surfaces S2 may have a linear shape. Further, one of the third side surfaces S3 may have a concave shape, and the other of the third side surfaces S3 may have a linear shape. Both ends of a concavely-curved one of the first side surfaces S1 may be connected to one end of a linear one of the second side surfaces S2 and one end of a linear one of the third side surfaces S3, respectively. Both ends of a linear one of the first side surfaces S1 may be connected to one end of a concavely-curved one of the second side surfaces S2 and one end of a concavely-curved one of the third side surfaces S3, respectively.

In the case where some of the bottom electrodes BE has the shape of FIG. 15E, the bottom electrodes BE may be disposed to form an arrangement shown in FIG. 16E. Referring to FIG. 16E, bottom electrodes BE having the shape of FIG. 15E may be arranged around a bottom electrode BE having a circular shape. For example, the bottom electrode BE having the circular shape may be disposed between a pair of the bottom electrodes BE arranged in the second direction D2, between another pair of the bottom electrodes BE arranged in the third direction D3, and between other pair of the bottom electrodes BE arranged in the fourth direction D4. In this case, the bottom electrode BE having the circular shape may have a rounded side surface Sr facing a concave side surface of each of the bottom electrodes BE having the shape of FIG. 15E. Accordingly, the bottom electrode BE having the circular shape may be disposed equidistant apart from neighboring ones of the bottom electrodes BE by a distance d.

In the case where at least one of the bottom electrodes BE has a circular shape, the bottom electrodes BE may be disposed to form an arrangement shown in FIG. 16F, but example embodiments of the inventive concept may not be limited thereto. Referring to FIG. 16F, bottom electrodes BE having a shape of FIG. 14 may be arranged around a bottom electrode BE having a circular shape. For example, the bottom electrode BE having the circular shape may be disposed between a pair of the bottom electrodes BE arranged in the second direction D2, between another pair of the bottom electrodes BE arranged in the third direction D3, and between other pair of the bottom electrodes BE arranged in the fourth direction D4. In this case, the bottom electrode BE having the circular shape may have a rounded side surface Sr facing a concave side surface of each of the bottom electrodes BE having the shape of FIG. 14. Accordingly, the bottom electrode BE having the circular shape may be disposed equidistant apart from neighboring ones of the bottom electrodes BE by a distance d.

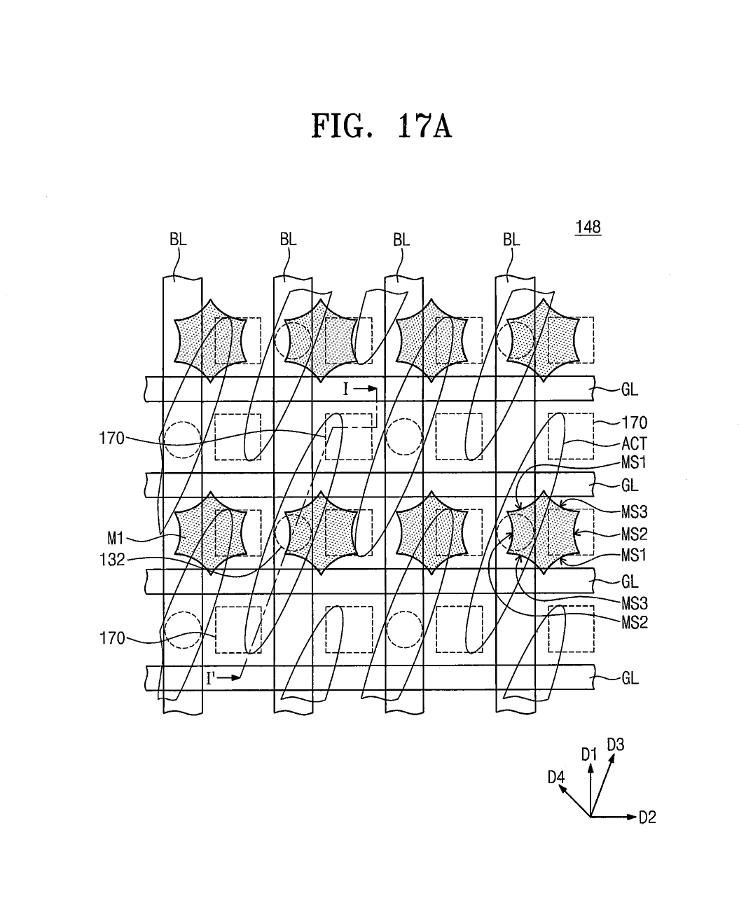

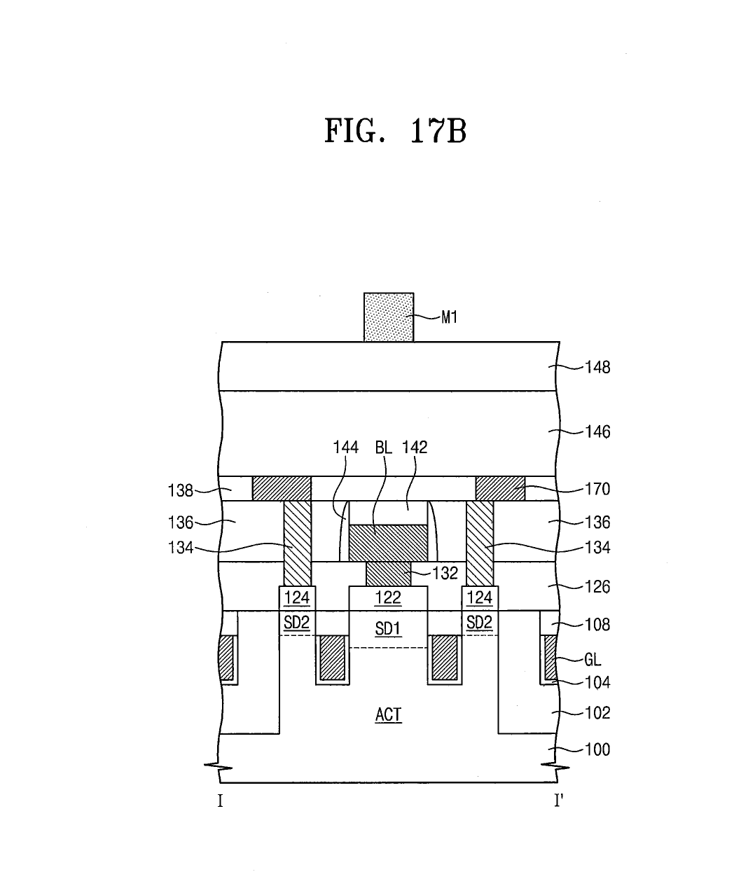

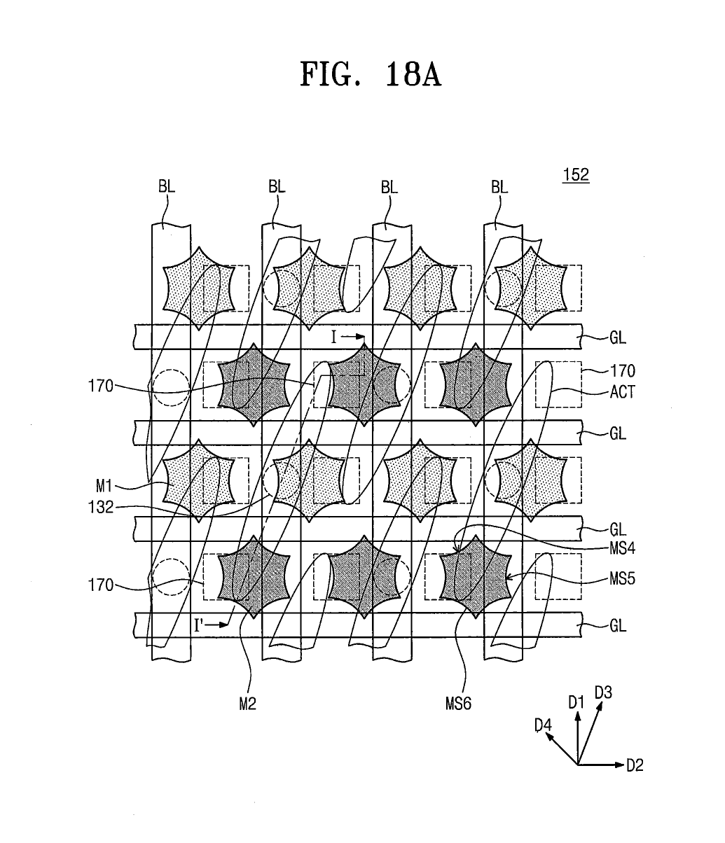

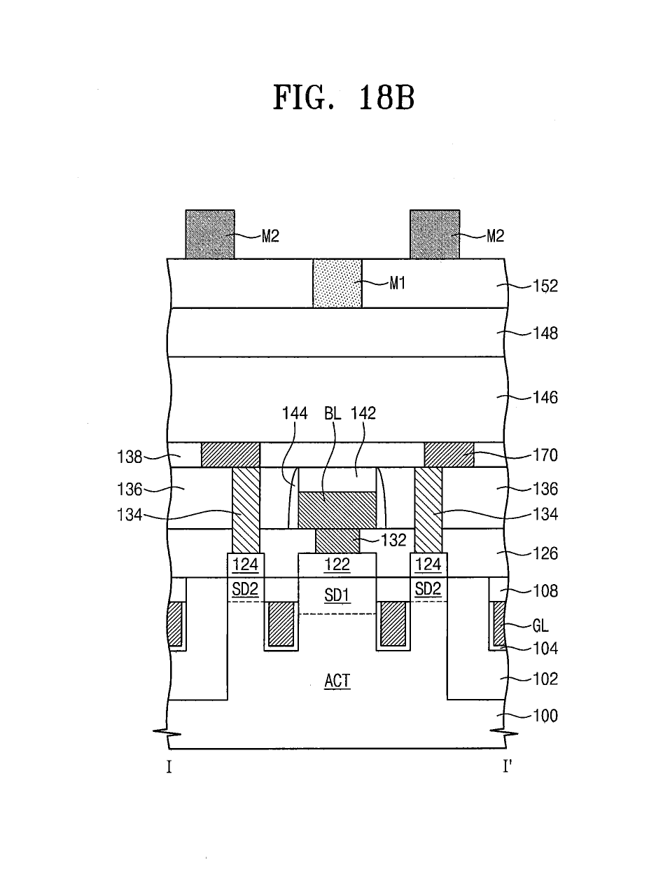

FIGS. 17A and 18A are plan views illustrating a method of fabricating a semiconductor device, according to a further embodiment of the inventive concept, and FIGS. 17B and 18B are sectional views taken along lines I-I′ of FIGS. 17A and 18A, respectively. For concise description, an element or a step previously described with reference to FIGS. 6A through 11A and 6B through 11B may be identified by a similar or identical reference number without repeating an overlapping description thereof.

Referring to FIGS. 17A and 17B, a device isolation layer 102 may be formed on a substrate 100 to define active regions ACT. The device isolation layer 102 may be formed using, for example, a shallow trench isolation (STI) process. Each of the active regions ACT may be shaped like a bar elongated in a third direction D3. For example, a longitudinal axis of each active region ACT may be parallel to the third direction D3, which is at an angle to two orthogonal directions (for example, first and second directions D1 and D2). Second doped regions SD2 may be formed in each of the active regions ACT. The second doped regions SD2 may be formed by an ion implantation process.

Gate lines GL may be formed in the substrate 100 to cross the active regions ACT. The gate lines GL may extend parallel to the second direction D2 and may be formed spaced apart from each other in the first direction D1. Gate insulating patterns 104 may be formed between the gate lines GL and the active regions ACT and between the gate lines GL and the device isolation layer 102. First capping patterns 108 may be formed on top surfaces of the gate lines GL, respectively. In example embodiments, the gate lines GL, the gate insulating patterns 104, and the first capping patterns 108 may be formed by substantially the same method as that of the embodiments previously described with reference to FIGS. 6A and 6B.

An ion implantation process may be performed to form a first doped region SD1 in a portion of each active region ACT positioned between an adjacent pair of the gate lines GL. The first doped region SD1 may be formed to have a depth greater than that of the second doped regions SD2, when measured from a top surface of the substrate 100.

A doped poly-silicon layer, a doped single crystalline silicon layer, or a conductive layer may be formed on the substrate 100 and then may be patterned to form a first pad 122 and second pads 124. The first pad 122 may be connected to the first doped region SD1, and the second pads 124 may be connected to the second doped regions SD2, respectively. A first interlayer insulating layer 126 may be formed on the first and second pads 122 and 124.

A bit line contact 132 may be formed to penetrate the first interlayer insulating layer 126, and a bit line BL may be formed on the first interlayer insulating layer 126 and may be connected to the first pad 122 through the bit line contact 132. A second capping pattern 142 may be formed on a top surface of the bit line BL, and bit line spacers 144 may be formed on both side surfaces of the bit line BL. The formation of the bit line contact 132, the bit line BL, the second capping pattern 142, and the bit line spacers 144 may be formed by substantially the same method as that of the embodiments previously described with reference to FIGS. 6A and 6B.

A second interlayer insulating layer 136 may be formed on the first interlayer insulating layer 126. A planarization process may be performed on the second interlayer insulating layer 136, and thus, the second interlayer insulating layer 136 may be formed to have a top surface coplanar with that of the second capping pattern 142. Buried contacts 134 may be formed to penetrate the second and first interlayer insulating layers 136 and 126. For example, the buried contacts 134 may be connected to the second pads 124, respectively.

A third interlayer insulating layer 138 may be formed on the second interlayer insulating layer 136. The third interlayer insulating layer 138 may be formed using, for example, a chemical vapor deposition process and may include, for example, a silicon nitride layer or a silicon oxynitride layer. Conductive pads 170 may be connected to the buried contacts 134, respectively, through the third interlayer insulating layer 138. The formation of the conductive pads 170 may include forming holes to penetrate the third interlayer insulating layer 138 and expose the buried contacts 134, respectively, forming a conductive layer on the third interlayer insulating layer 138 to fill the holes, and planarizing the conductive layer to expose a top surface of the third interlayer insulating layer 138. As another example, the conductive pads 170 may be formed by forming a conductive layer on the second interlayer insulating layer 136 and patterning the conductive layer.

A first mold layer 146 and a lower mask layer 148 may be sequentially formed on the third interlayer insulating layer 138. First mask patterns M1 may be formed on the lower mask layer 148. When viewed in a plan view, the first mask patterns M1 may be arranged in the first direction D1 and the second direction D2 to form a plurality of rows and a plurality of columns. N-th ones of the first mask patterns M1 constituting each row may form an n-th column, where n is an integer. When viewed in a plan view, each of the first mask patterns M1 may be formed to be overlapped with a corresponding one of the conductive pads 170.

Each of the first mask patterns M1 may include first mask side surfaces MS1, which are provided to face each other, second mask side surfaces MS2, which are provided between the first mask side surfaces MS1 to face each other, and third mask side surfaces MS3, which are provided between the first mask side surfaces MS1 to face each other. One end of each of the second mask side surfaces MS2 may be connected to one end of each of the first mask side surfaces MS1, and the other end of each of the second mask side surfaces MS2 may be connected to one end of each of the third mask side surfaces MS3. The other end of each of the first mask side surfaces MS1 may be adjacent to the other end of each of the third mask side surfaces MS3.

The first mask side surfaces MS1 may face each other in a fourth direction D4 crossing all of the first, second, and third directions D1, D2, and D3. The second mask side surfaces MS2 may be provided to face each other in the second direction D2, and the third mask side surfaces MS3 may be provided to face each other in the third direction D3.

In example embodiments, when viewed in a plan view, each of the first, second, and third mask side surfaces MS1, MS2, and MS3 may have a concave shape. As an example, the first mask side surfaces MS1, the second mask side surfaces MS2, and the third mask side surfaces MS3 may be concavely curved in a direction toward a center of the first mask pattern M1. However, in certain embodiments, when viewed in a plan view, at least one of the first, second, and third mask side surfaces MS1, MS2, and MS3 may have a convex or linear shape. As an example, at least one of the first, second, and third mask side surfaces may be convexly curved in a direction away from the center of the first mask pattern M1 or may have a linear shape extending parallel to a specific direction.

Referring to FIGS. 18A and 18B, an upper mask layer 152 may be formed on the lower mask layer 148 to cover the first mask patterns M1. Second mask patterns M2 may be formed on the upper mask layer 152.

When viewed in a plan view, the second mask patterns M2 may be arranged in the first direction D1 and the second direction D2 to form a plurality of rows and a plurality of columns. N-th ones of the second mask patterns M2 constituting each row may form an n-th column, where n is an integer. When viewed in a plan view, the second mask patterns M2 may be formed spaced apart from the first mask patterns M1. The second mask patterns M2 may be formed on the upper mask layer 152 in such a way that each of them is placed on a position between a pair of the first mask patterns M1 adjacent to each other in the fourth direction D4 and between another pair of the first mask patterns M1 adjacent to each other in the third direction D3. When viewed in a plan view, each of the second mask patterns M2 may be formed to be overlapped with a corresponding one of the conductive pads 170.

Each of the second mask patterns M2 may include fourth mask side surfaces MS4, which are provided to face each other, fifth mask side surfaces MS5, which are provided between the fourth mask side surfaces MS4 to face each other, and sixth mask side surfaces MS6, which are provided between the fourth mask side surfaces MS4 to face each other. The fourth mask side surfaces MS4 may face each other in the fourth direction D4, and the fifth mask side surfaces MS5 may face each other in the second direction D2. The sixth mask side surfaces MS6 may face each other in the third direction D3. In example embodiments, when viewed in a plan view, each of the fourth, fifth, and sixth mask side surfaces MS4, MS5, and MS6 may have a concave shape. As an example, each of the fourth, fifth, and sixth mask side surfaces MS4, MS5, and MS6 may be concavely curved in a direction toward a center of the second mask pattern M2. However, in certain embodiments, when viewed in a plan view, at least one of the fourth, fifth, and sixth mask side surfaces MS4, MS5, and MS6 may have a convex or linear shape. For example, at least one of the fourth, fifth, and sixth mask side surfaces MS4, MS5, and MS6 may be convexly curved in a direction away from a center of the second mask pattern M2 or may have a linear shape extending parallel to a specific direction.

In example embodiments, the first and second mask patterns M1 and M2 may have substantially the same shape, but in other example embodiments, at least one of the first and second mask patterns M1 and M2 may be formed to have a different shape from the others.

The subsequent process may be performed in substantially the same manner as that of the embodiments described with reference to FIGS. 8A through 11A and 8B through 11B.

Referring back to FIGS. 12A and 12B, bottom electrodes BE may be formed using the first and second mask patterns M1 and M2, and then, a dielectric layer 150 and a top electrode TE may be sequentially formed on the third interlayer insulating layer 138 to cover the bottom electrodes BE.

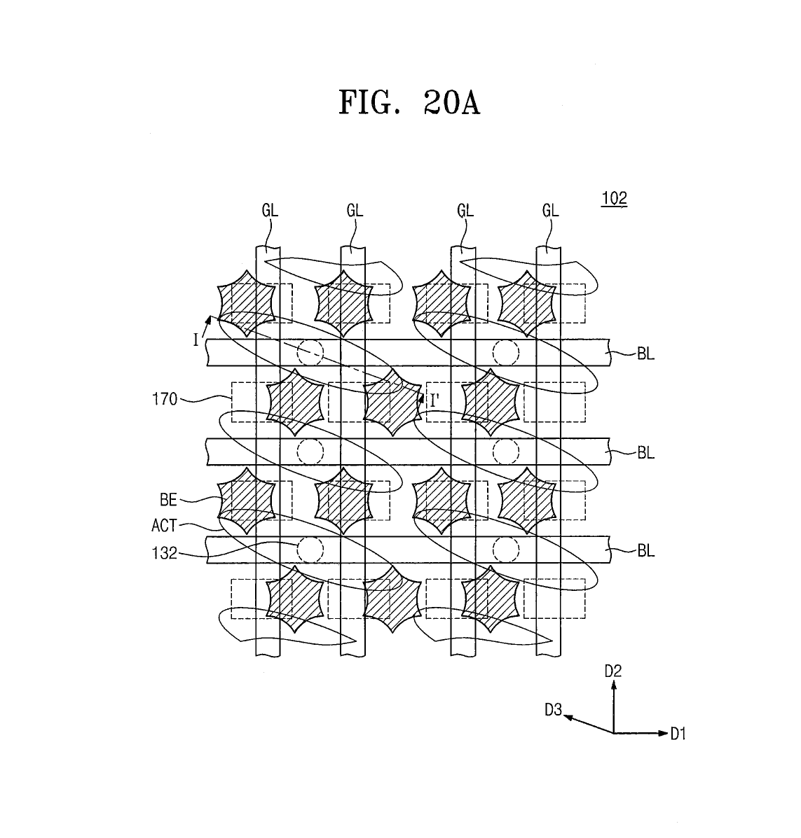

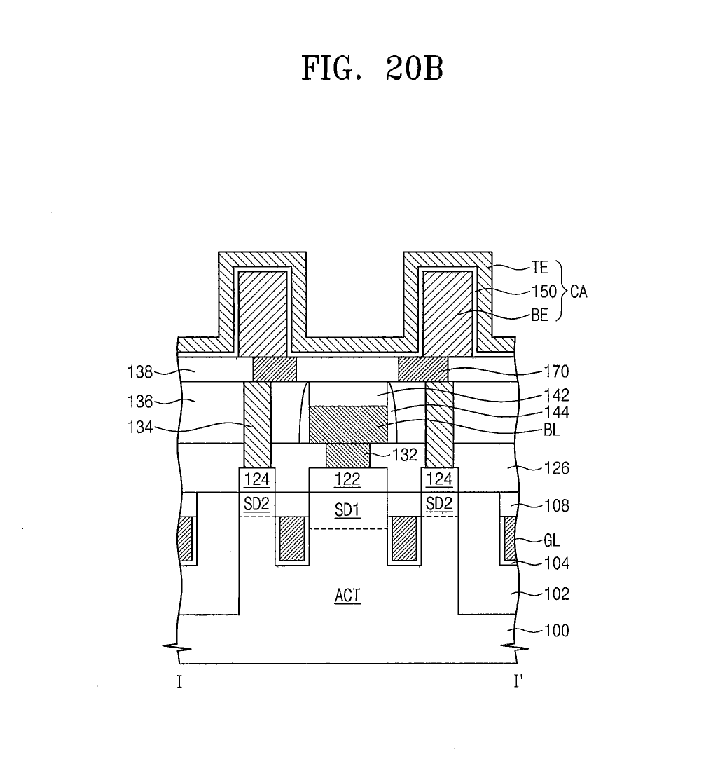

FIG. 20A is a plan view illustrating a semiconductor device according to still further embodiments of the inventive concept, and FIG. 20B is a sectional view taken along line I-I′ of FIG. 20A. For concise description, an element previously described with reference to FIGS. 12A and 12B may be identified by a similar or identical reference number without repeating an overlapping description thereof.

Referring to FIGS. 20A and 20B, a device isolation layer 102 may be provided on a substrate 100 to define active regions ACT. When viewed in a plan view, each of the active regions ACT may be shaped like a bar, whose longitudinal axis is parallel to a third direction D3 or is at an angle to first and second directions D1 and D2 crossing each other. According to the embodiments described with reference to FIG. 12A, the active regions ACT may be arranged in a zigzag manner in the second direction D2, but according to the present embodiments, the active regions ACT may be arranged in a columnar arrangement manner in the second direction D2, as shown in FIG. 20A.

In the present embodiment, a semiconductor device, except for the afore-described differences, may be configured to have substantially the same features as those of FIGS. 12A and 12B. Further, the bottom electrodes BE may be configured to have substantially the same arrangement and shapes as those described with reference to FIGS. 13, 14, 15A through 15E, and 16A through 16F.

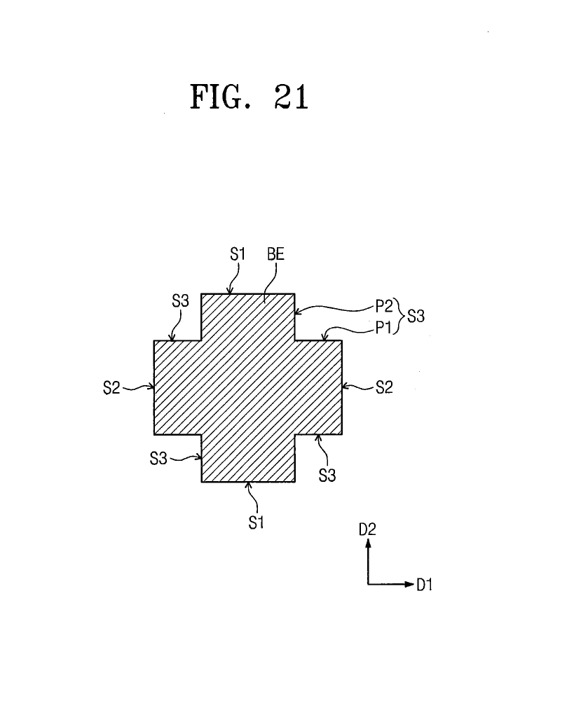

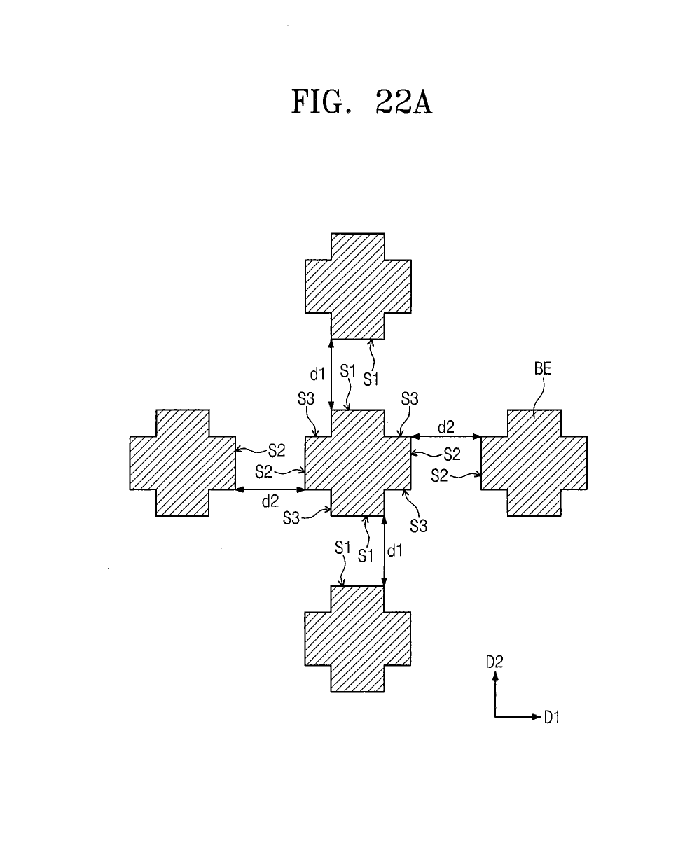

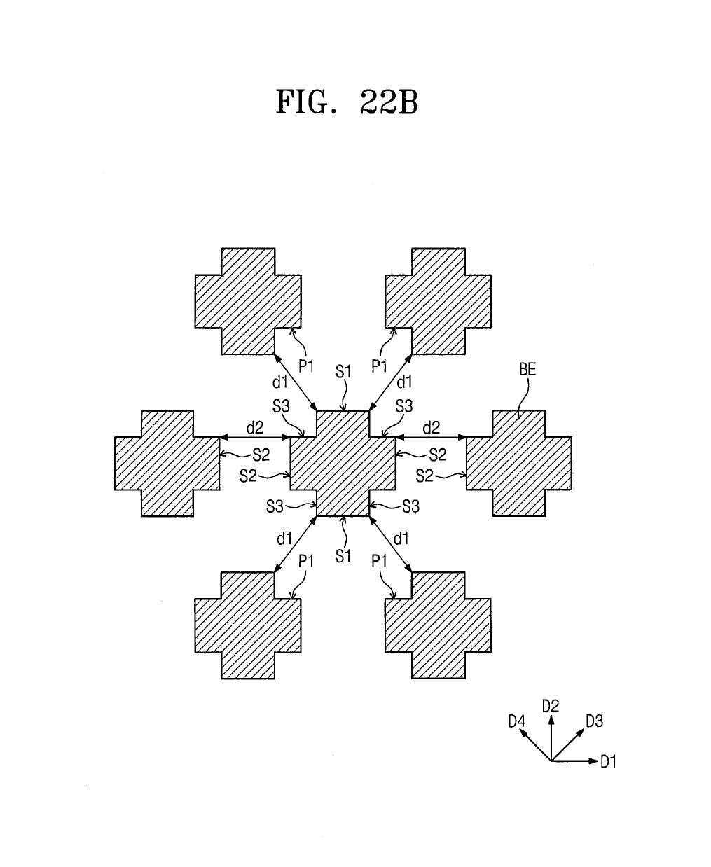

FIG. 21 is a plan view illustrating a modified planar shape of each bottom electrode provided in a semiconductor device according to example embodiments of the inventive concept. FIGS. 22A and 22B are plan views illustrating planar arrangements of bottom electrodes, whose planar shapes are shaped like that shown in FIG. 21.

Referring to FIG. 21, when viewed in a plan view, a bottom electrode BE may include first side surfaces S1, which are provided to face each other, and second side surfaces S2, which are provided between the first side surfaces S1 to face each other. The first side surfaces S1 may have a linear shape extending parallel to a first direction D1, and the second side surfaces S2 may have a linear shape extending parallel to a second direction D2 crossing the first direction D1. The bottom electrode BE may further include third side surfaces S3 connecting the first and second side surfaces S1 and S2 to each other. For example, each of the third side surfaces S3 may include a first portion P1 extending parallel to the first direction D1 and a second portion P2 extending parallel to the second direction D2. In the present embodiment, the bottom electrode BE may be shaped like a cross.

The bottom electrodes BE having the shape of FIG. 21 may be two-dimensionally arranged on a substrate 100 to form a square arrangement, as shown in FIG. 1A, or a honeycomb arrangement, as shown in FIG. 12A.

In the case where the bottom electrodes BE are disposed to form a square arrangement, as shown in FIG. 22A, a pair of the bottom electrodes BE, which are positioned adjacent to the first side surfaces S1, respectively, may be disposed spaced apart from each other in the second direction D2, and another pair of the bottom electrodes BE, which are positioned adjacent to the second side surfaces S2, respectively, may be disposed spaced apart from each other in the first direction D1. The first side surfaces S1 may be disposed to face respective first side surfaces S1 of the pair of the bottom electrodes BE paired and arranged in the second direction D2, and the second side surfaces S2 may be disposed to face respective second side surfaces S2 of the pair of the bottom electrodes BE paired and arranged in the first direction D1. The first side surfaces S1 may be disposed equidistant apart from respective ones of the bottom electrodes BE paired and arranged in the second direction D2 by a first distance d1. Further, the second side surfaces S2 may be disposed equidistant apart from respective ones of the bottom electrodes BE paired and arranged in the first direction D1 by a second distance d2. In example embodiments, the first distance d1 may be substantially equal to the second distance d2.

In the case where the bottom electrodes BE are disposed to form a honeycomb arrangement, as shown in FIG. 22B, each of the bottom electrodes BE may be disposed between a pair of the bottom electrodes BE arranged in the first direction D1, between another pair of the bottom electrodes BE arranged in a third direction D3 at an angle to both the first and second directions D1 and D2, between other pair of the bottom electrodes BE arranged in a fourth direction D4 at an angle to all of the first to third directions D1, D2, and D3.

Each of the first side surfaces S1 may be disposed to face a pair of the first portions P1, each of which is included in a corresponding one of two pairs of the bottom electrodes BE arranged in the third and fourth directions D3 and D4. The second side surfaces S2 may be disposed to face respective second side surfaces S2 of the pair of the bottom electrodes BE paired and arranged in the first direction D1. The first side surfaces S1 may be disposed spaced apart from respective ones of the bottom electrodes BE paired and arranged in each of the third and fourth directions D3 and D4 by a first distance d1. Further, the second side surfaces S2 may be disposed equidistant apart from respective ones of the bottom electrodes BE paired and arranged in the first direction D1 by a second distance d2. In example embodiments, the first distance d1 may be substantially equal to the second distance d2.

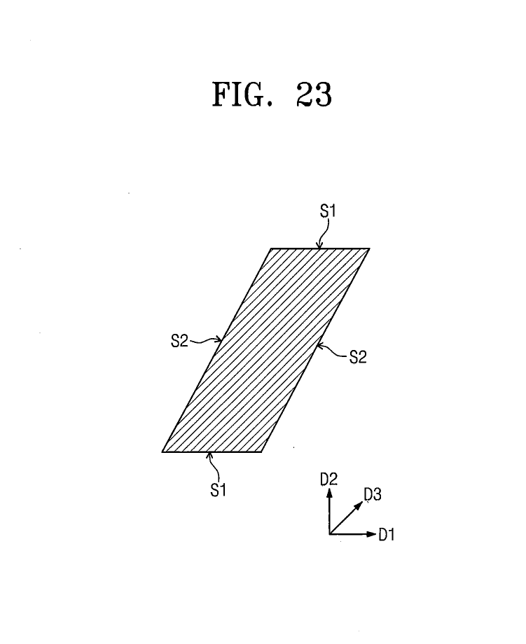

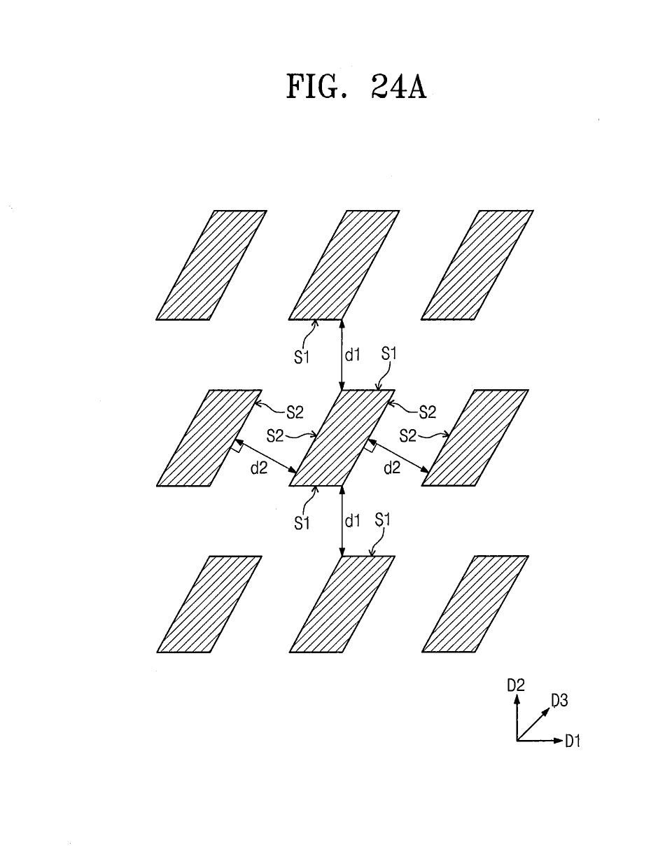

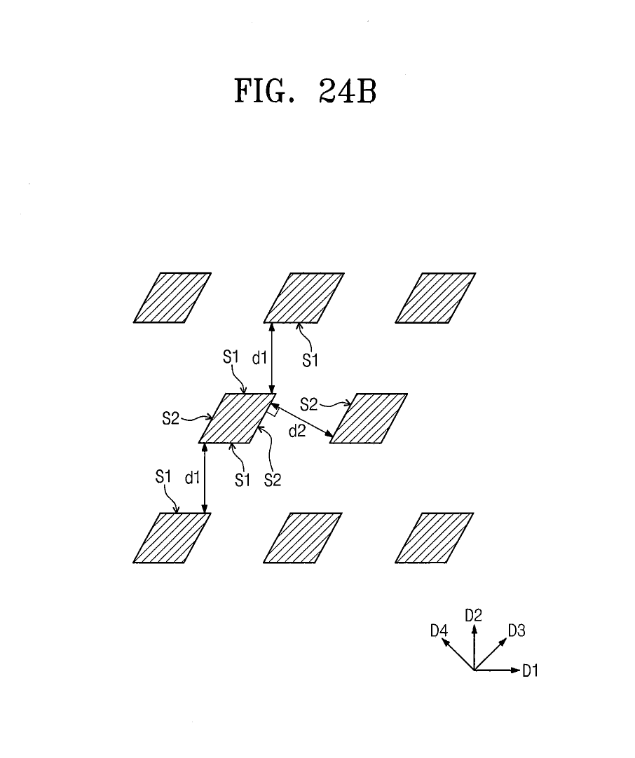

FIG. 23 is a plan view illustrating another modified planar shape of each bottom electrode provided in a semiconductor device according to example embodiments of the inventive concept, and FIGS. 24A and 24B are plan views illustrating planar arrangements of bottom electrodes, whose planar shapes are shaped like that shown in FIG. 23.

Referring to FIG. 23, when viewed in a plan view, a bottom electrode BE may include first side surfaces S1, which are provided to face each other, and second side surfaces S2, which are provided between the first side surfaces S1 to face each other. The first side surfaces S1 may extend parallel to a first direction D1, and the second side surfaces S2 may extend parallel to a third direction D3. Here, the first direction D1 may be orthogonal to a second direction D2, and the third direction D3 may be at an angle to both the first and second directions D1 and D2. In the present embodiment, the bottom electrode BE may be shaped like a parallelogram.

The bottom electrodes BE having the shape of FIG. 23 may be two-dimensionally arranged on a substrate 100 to form a square arrangement, as shown in FIG. 1A, or a honeycomb arrangement, as shown in FIG. 12A.

In the case where the bottom electrodes BE are disposed to form a square arrangement, a pair of the bottom electrodes BE, which are positioned adjacent to the first side surfaces S1, respectively, may be disposed spaced apart from each other in the second direction D2, and another pair of the bottom electrodes BE, which are positioned adjacent to the second side surfaces S2, respectively, may be disposed spaced apart from each other in the first direction D1, as shown in FIG. 24A. The first side surfaces S1 may be disposed to face respective first side surfaces S1 of the pair of the bottom electrodes BE paired and arranged in the second direction D2, and the second side surfaces S2 may be disposed to face respective second side surfaces S2 of the pair of the bottom electrodes BE paired and arranged in the first direction D1. The first side surfaces S1 may be disposed equidistant apart from respective ones of the bottom electrodes BE paired and arranged in the second direction D2 by a first distance d1. Further, the second side surfaces S2 may be disposed equidistant apart from respective ones of the bottom electrodes BE paired and arranged in the first direction D1 by a second distance d2. In example embodiments, the first distance d1 may be substantially equal to the second distance d2.

In the case where the bottom electrodes BE are disposed to form a honeycomb arrangement, as shown in FIG. 24B, the first side surfaces S1 may be disposed to face respective first side surfaces S1 of the pair of the bottom electrodes BE paired and arranged in the third direction D3, and the second side surfaces S2 may be disposed to face respective second side surfaces S2 of the pair of the bottom electrodes BE paired and arranged in the first direction D1. The second side surfaces S2 may be parallel to respective second side surfaces S2 of the pair of the bottom electrodes BE paired and arranged in the third direction D3. The first side surfaces S1 may be disposed equidistant apart from respective ones of the bottom electrodes BE paired and arranged in the third direction D3 by a first distance d1. Further, the second side surfaces S2 may be disposed equidistant apart from respective ones of the bottom electrodes BE paired and arranged in the first direction D1 by a second distance d2. In example embodiments, the first distance d1 may be substantially equal to the second distance d2.

According to example embodiments of the inventive concept, each of the bottom electrodes BE can be formed to have an increased surface area in a limited planar area, without concern for breakage of electric isolation. Accordingly, a capacitor of a semiconductor device can have an increased capacitance.

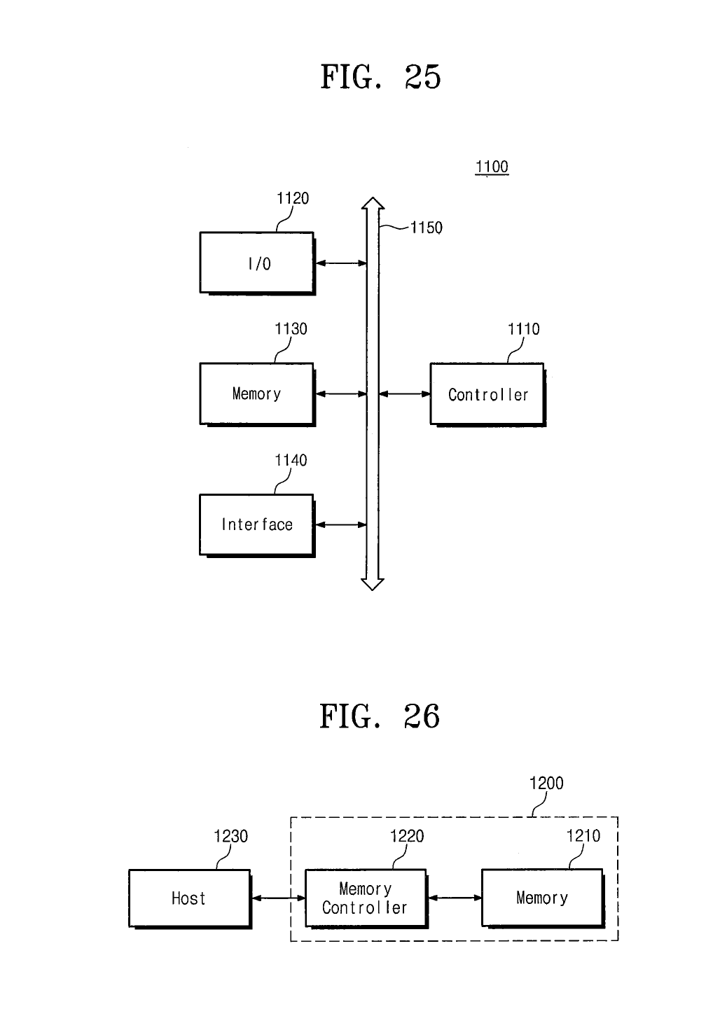

FIG. 25 is a schematic block diagram illustrating an example of electronic systems including a semiconductor device according to example embodiments of the inventive concept.

Referring to FIG. 25, an electronic system 1100 according to example embodiments of the inventive concept may include a controller 1110, an input/output (I/O) unit 1120, a memory device 1130, an interface unit 1140 and a data bus 1150. At least two of the controller 1110, the I/O unit 1120, the memory device 1130 and the interface unit 1140 may communicate with each other through the data bus 1150. The data bus 1150 may correspond to a path through which electrical signals are transmitted.

The controller 1110 may include at least one of a microprocessor, a digital signal processor, a microcontroller or another logic device. The other logic device may have a similar function to any one of the microprocessor, the digital signal processor and the microcontroller. The I/O unit 1120 may include a keypad, a keyboard or a display unit. The memory device 1130 may store data and/or commands. The memory device 1130 may include one of semiconductor devices according to example embodiments of the inventive concept. In other embodiments, the memory device 1130 may further include a semiconductor memory device, which is of a different type from the semiconductor memory devices according to the afore-described embodiments of the inventive concept. The interface unit 1140 may transmit electrical data to a communication network or may receive electrical data from a communication network.

The electronic system 1100 may be applied to a laptop computer, a personal digital assistant (PDA), a portable computer, a web tablet, a wireless phone, a mobile phone, a digital music player, a memory card or an electronic product.

FIG. 26 is a schematic block diagram illustrating an example of memory cards including the semiconductor memory device according to the embodiments of the inventive concept.

Referring to FIG. 26, a memory card 1200 according to example embodiments of the inventive concept may include a memory device 1210. The memory device 1210 may include at least one of the semiconductor memory devices according to the afore-described embodiments of the inventive concept. In other embodiments, the memory device 1210 may further include a semiconductor memory device, which is of a different type from the semiconductor memory devices according to the afore-described embodiments of the inventive concept. The memory card 1200 may include a memory controller 1220 that controls data communication between a host 1230 and the memory device 1210.

According to example embodiments of the inventive concept, each of the bottom electrodes BE can be formed to have an increased surface area in a limited planar area, without concern for breakage of electric isolation. This makes it possible to increase capacitance of a capacitor of a semiconductor device.

While example embodiments of the inventive concepts have been particularly shown and described, it will be understood by one of ordinary skill in the art that variations in form and detail may be made therein without departing from the spirit and scope of the attached claims.

1. A semiconductor device, comprising:
bottom electrodes two-dimensionally arranged on a substrate; and
transistors connected to the bottom electrodes, respectively,
wherein each of the bottom electrodes comprises first side surfaces facing each other in a first direction and second side surfaces facing each other in a second direction crossing the first direction,
a first one of the first side surfaces of a first one of the bottom electrodes is spaced apart from one of the side surfaces of a second one of the bottom electrodes adjacent thereto in the first direction by a first distance,
a first one of the second side surfaces of the first one of the bottom electrodes is spaced apart from one of the side surfaces of a third one of the bottom electrodes adjacent thereto in the second direction by a second distance, and
at least one of the first and second side surfaces has a concave shape, when viewed in a plan view.

2. The device of claim 1, wherein:
a second one of the first side surfaces of the first one of the bottom electrodes is spaced apart from one of the side surfaces of a fourth one of the bottom electrodes adjacent thereto in the first direction by the first distance,
a second one of the second side surfaces of the first one of the bottom electrodes is spaced apart from one of the side surfaces of a fifth one of the bottom electrodes adjacent thereto in the second direction by the second distance, and
the first and second distances are a minimum separation distance required for electrical separation between the bottom electrodes adjacent to each other.

3. The device of claim 1, wherein the first and second distances are substantially equal to each other.

4. The device of claim 1, further comprising bit lines provided between the bottom electrodes and the transistors and connected to the transistors.

5. The device of claim 1, wherein, when viewed in a plan view, the first side surfaces have shapes symmetrical to each other.

6. The device of claim 5, wherein each of the first side surfaces has the concave shape.

7. The device of claim 6, wherein, when viewed in a plan view, the second side surfaces have shapes symmetrical to each other, and each of the second side surfaces has the concave shape.

8. The device of claim 6, wherein, when viewed in a plan view, the second side surfaces have shapes symmetrical to each other, and each of the second side surfaces has a linear shape extending parallel to the first direction.

9.-11. (canceled)

12. The device of claim 1, wherein, when viewed in a plan view, the first side surfaces have shapes asymmetrical to each other.

13. The device of claim 12, wherein one of the first side surfaces has the concave shape, and the other of the first side surfaces has a convex shape.

14.-16. (canceled)

17. The device of claim 13, wherein, when viewed in a plan view, the second side surfaces have shapes asymmetrical to each other,
one of the second side surfaces has the concave shape, and
the other of the second side surfaces has the convex shape.

18. The device of claim 1, wherein each of the bottom electrodes further comprises third side surfaces facing each other in a third direction crossing both the first and second directions,
a first one of the third side surfaces of the first one of the bottom electrodes is spaced apart from one of the side surfaces of a fourth one of the bottom electrodes adjacent thereto in the third direction by a third distance, and
at least one of the first, second, and third side surfaces has a concave shape when viewed in the plan view.

19. The device of claim 18, wherein:
a second one of the first side surfaces of the first one of the bottom electrodes is spaced apart from one of the side surfaces of a fifth one of the bottom electrodes adjacent thereto in the first direction by the first distance,
a second one of the second side surfaces of the first one of the bottom electrodes is spaced apart from one of the side surfaces of a sixth one of the bottom electrodes adjacent thereto in the second direction by the second distance,
a second one of the third side surfaces of the first one of the bottom electrodes is spaced apart from one of the side surfaces of a seventh one of the bottom electrodes adjacent thereto in the third direction by the third distance, and
the first, second, and third distances are a minimum separation distance required for electrical separation between the bottom electrodes adjacent to each other.

20. The device of claim 18, wherein the first, second, and third distances are substantially equal to each other.

21.-23. (canceled)

24. The device of claim 1, wherein, when viewed in a plan view, at least one of the first and second side surfaces is concavely curved toward a center of the respective one of the bottom electrodes.

25. The device of claim 1, wherein, when viewed in a plan view, one of the first and second side surfaces has the concave shape and the other one of the first and second side surfaces has a convex shape, and
the one of the first and second side surfaces having the concave shape of each of the bottom electrodes is disposed to face the one of side surfaces having the convex shape of an adjacent one of the bottom electrodes.

26. (canceled)

27. A semiconductor device, comprising:
bottom electrodes two-dimensionally arranged on a substrate; and
transistors connected to the bottom electrodes, respectively,
wherein, when viewed in a plan view, at least one of the bottom electrodes has a shape different from the others.

28. The device of claim 27, wherein one of a pair of the bottom electrodes, whose shapes are different from each other in the plan view has a concavely-curved side surface, and the other of the pair of the bottom electrodes has a convexly-curved side surface facing the concavely-curved side surface.

29. The device of claim 27, wherein each of the bottom electrodes comprises first side surfaces facing each other in a first direction and second side surfaces facing each other in a second direction crossing the first direction,
a first one of the first side surfaces of a first one of the bottom electrodes is spaced apart from one of the side surfaces of a second one of the bottom electrodes adjacent thereto in the first direction by a first distance, and
a first one of the second side surfaces of the first one of the bottom electrodes is spaced apart from one of the side surfaces of a third one of the bottom electrodes adjacent thereto in the second direction by a second distance.

30. The device of claim 29, wherein the first distance is substantially equal to the second distance.

31.-39. (canceled)
